(19) United States
(12) Patent Application Publication
(10) Pub. No.: US 2009/0183764 A1
(43) Pub. Date: Jul. 23, 2009

(54) Detachable Louver System

(75) Inventor: Dallas W. Meyer, Prior Lake, MN (US)

Correspondence Address: Workman Nydegger;1000 Eagle Gate Tower, 60 East South Temple, Salt Lake City, UT, 84111, US

(73) Assignee: TENKSOLAR, INC, Prior Lake, MN (US)

(21) Appl. No.: 12/357,277

(22) Filed: Jan. 21, 2009

Related U.S. Application Data
(60) Provisional application No. 61/022,232, filed on Jan. 18, 2008.
(60) Provisional application No. 61/022,264, filed on Jan. 18, 2008.
(60) Provisional application No. 61/022,253, filed on Jan. 18, 2008.
(60) Provisional application No. 61/022,267, filed on Jan. 18, 2008.
(60) Provisional application No. 61/022,228, filed on Jan. 18, 2008.
(60) Provisional application No. 61/022,234, filed on Jan. 18, 2008.
(60) Provisional application No. 61/022,236, filed on Jan. 18, 2008.
(60) Provisional application No. 61/022,240, filed on Jan. 18, 2008.
(60) Provisional application No. 61/022,242, filed on Jan. 18, 2008.
(60) Provisional application No. 61/022,277, filed on Jan. 18, 2008.
(60) Provisional application No. 61/022,278, filed on Jan. 18, 2008.
(60) Provisional application No. 61/025,570, filed on Feb. 1, 2008.
(60) Provisional application No. 61/022,245, filed on Jan. 18, 2008.
(60) Provisional application No. 61/025,575, filed on Feb. 1, 2008.
(60) Provisional application No. 61/022,246, filed on Jan. 18, 2008.
(60) Provisional application No. 61/022,258, filed on Jan. 18, 2008.
(60) Provisional application No. 61/022,263, filed on Jan. 18, 2008.
(60) Provisional application No. 61/022,249, filed on Jan. 18, 2008.
(60) Provisional application No. 61/022,280, filed on Jan. 18, 2008.
(60) Provisional application No. 61/022,252, filed on Jan. 18, 2008.
(60) Provisional application No. 61/025,578, filed on Feb. 1, 2008.
(60) Provisional application No. 61/025,581, filed on Feb. 1, 2008.
(60) Provisional application No. 61/033,203, filed on Mar. 3, 2008.
(60) Provisional application No. 61/035,976, filed on Mar. 12, 2008.
(60) Provisional application No. 61/058,485, filed on Jun. 3, 2008.
(60) Provisional application No. 61/080,628, filed on Jul. 14, 2008.
(60) Provisional application No. 61/091,642, filed on Aug. 25, 2008.
(60) Provisional application No. 61/101,344, filed on Sep. 30, 2008.
(60) Provisional application No. 61/111,239, filed on Nov. 4, 2008.
(60) Provisional application No. 61/042,629, filed on Apr. 4, 2008.
(60) Provisional application No. 61/045,229, filed on Apr. 15, 2008.

(51) Int. Cl. H01L 31/052; B32B 37/00; E06B 7/08

(52) U.S. Cl. 136/246; 156/250; 52/473

(57) ABSTRACT

One example embodiment includes a detachable louver system comprising primary louvers and a frame. The primary louvers are arranged substantially parallel to each other and are configured to reflect light rays incident on the primary louvers onto photovoltaic areas of a photovoltaic module. The frame is configured to support the primary louvers and to removably couple the detachable louver system to the photovoltaic module.

### CROSS-REFERENCE TO RELATED APPLICATIONS

This patent application:

(i) claims the benefit of and priority to U.S. Provisional Patent Application Ser. No. 61/022,232, filed Jan. 18, 2008 by Dallas W. Meyer for POLISHED AND TEXTURED BACK CONTACTS FOR A THIN-FILM PHOTOVOLTAIC SYSTEM;

(ii) claims the benefit of and priority to U.S. Provisional Patent Application Ser. No. 61/022,264, filed Jan. 18, 2008 by Dallas W. Meyer for A THIN PROTECTIVE FILM FOR PHOTOVOLTAIC SYSTEMS;

(iii) claims the benefit of and priority to U.S. Provisional Patent Application Ser. No. 61/022,253, filed Jan. 18, 2008 by Dallas W. Meyer for A FILM LEVEL ENCAPSULATION PHOTOVOLTAIC SYSTEM;

(iv) claims the benefit of and priority to U.S. Provisional Patent Application Ser. No. 61/022,267, filed Jan. 18, 2008 by Dallas W. Meyer for A PHOTOVOLTAIC SYSTEM WITH EMBEDDED ELECTRONICS;

(v) claims the benefit of and priority to U.S. Provisional Patent Application Ser. No. 61/022,228, filed Jan. 18, 2008 by Dallas W. Meyer for A SINGLE USE DIODE FOR A PHOTOVOLTAIC SYSTEM;

(vi) claims the benefit of and priority to U.S. Provisional Patent Application Ser. No. 61/022,234, filed Jan. 18, 2008 by Dallas W. Meyer for A HIGHLY COMPLIANT INTERCONNECT FOR A PHOTOVOLTAIC SYSTEM;

(vii) claims the benefit of and priority to U.S. Provisional Patent Application Ser. No. 61/022,236, filed Jan. 18, 2008 by Dallas W. Meyer for A FAULT TOLERANT PHOTOVOLTAIC SYSTEM;

(viii) claims the benefit of and priority to U.S. Provisional Patent Application Ser. No. 61/022,240, filed Jan. 18, 2008 by Dallas W. Meyer for INTEGRATED DEFECT MANAGEMENT FOR THIN-FILM PHOTOVOLTAIC SYSTEMS;

(ix) claims the benefit of and priority to U.S. Provisional Patent Application Ser. No. 61/022,242, filed Jan. 18, 2008 by Dallas W. Meyer for OPERATING FEATURES FOR INTEGRATED PHOTOVOLTAIC SYSTEMS;

(x) claims the benefit of and priority to U.S. Provisional Patent Application Ser. No. 61/022,277, filed Jan. 18, 2008 by Dallas W. Meyer for A PHOTOVOLTAIC SYSTEM USING NON-UNIFORM ILLUMINATION;

(xi) claims the benefit of and priority to U.S. Provisional Patent Application Ser. No. 61/022,278, filed Jan. 18, 2008 by Dallas W. Meyer for LOW MAGNIFICATION CONCENTRATED PHOTOVOLTAIC SYSTEM;

(xii) claims the benefit of and priority to U.S. Provisional Patent Application Ser. No. 61/025,570, filed Feb. 1, 2008 by Dallas W. Meyer for A SELF-DE-ICING PHOTOVOLTAIC SYSTEM;

(xiii) claims the benefit of and priority to U.S. Provisional Patent Application Ser. No. 61/022,245, filed Jan. 18, 2008 by Dallas W. Meyer for A VERY HIGH ASPECT RATIO THIN-FILM PHOTOVOLTAIC SYSTEM;

(xiv) claims the benefit of and priority to U.S. Provisional Patent Application Ser. No. 61/025,575, filed Feb. 1, 2008 by Dallas W. Meyer for PRODUCTION TESTING OF LARGE AREA PHOTOVOLTAIC MODULES;

(xv) claims the benefit of and priority to U.S. Provisional Patent Application Ser. No. 61/022,246, filed Jan. 18, 2008 by Dallas W. Meyer for A LONGITUDINALLY CONTINUOUS PHOTOVOLTAIC MODULE;

(xvi) claims the benefit of and priority to U.S. Provisional Patent Application Ser. No. 61/022,258, filed Jan. 18, 2008 by Dallas W. Meyer for A CONTINUOUS LARGE AREA PHOTOVOLTAIC SYSTEM;

(xvii) claims the benefit of and priority to U.S. Provisional Patent Application Ser. No. 61/022,263, filed Jan. 18, 2008 by Dallas W. Meyer for A BACK-ELECTRODE, LARGE AREA CONTINUOUS PHOTOVOLTAIC MODULE;

(xviii) claims the benefit of and priority to U.S. Provisional Patent Application Ser. No. 61/022,249, filed Jan. 18, 2008 by Dallas W. Meyer for CORRUGATED PHOTOVOLTAIC PANELS;

(xix) claims the benefit of and priority to U.S. Provisional Patent Application Ser. No. 61/022,280, filed Jan. 18, 2008 by Dallas W. Meyer for A VERY HIGH EFFICIENCY THIN-FILM PHOTOVOLTAIC SYSTEM;

(xx) claims the benefit of and priority to U.S. Provisional Patent Application Ser. No. 61/022,252, filed Jan. 18, 2008 by Dallas W. Meyer for A MULTI-USE GROUND BASED PHOTOVOLTAIC SYSTEM;

(xxi) claims the benefit of and priority to U.S. Provisional Patent Application Ser. No. 61/025,578, filed Feb. 1, 2008 by Dallas W. Meyer for A PREDICTIVE SYSTEM FOR DISTRIBUTED POWER SOURCE MANAGEMENT;

(xxii) claims the benefit of and priority to U.S. Provisional Patent Application Ser. No. 61/025,581, filed Feb. 1, 2008 by Dallas W. Meyer for A WEATHERPROOF CORRUGATED PHOTOVOLTAIC PANEL SYSTEM.

(xxiii) claims the benefit of and priority to U.S. Provisional Patent Application Ser. No. 61/033,203, filed Mar. 3, 2008 by Dallas W. Meyer for A STRUCTURALLY CONTINUOUS PHOTOVOLTAIC CORRUGATED PANEL AND PHOTOVOLTAIC SYSTEM;

(xxiv) claims the benefit of and priority to U.S. Provisional Patent Application Ser. No. 61/035,976, filed Mar. 12, 2008 by Dallas W. Meyer for A REDUNDANT SILICON SOLAR ARRAY;

(xxv) claims the benefit of and priority to U.S. Provisional Patent Application Ser. No. 61/058,485, filed Jun. 3, 2008 by Dallas W. Meyer for A HOME OWNER INSTALLED GROUND OR ROOF MOUNTED SOLAR SYSTEM;

(xxvi) claims the benefit of and priority to U.S. Provisional Patent Application Ser. No. 61/080,628, filed Jul. 14, 2008 by Dallas W. Meyer for A LOW COST SOLAR MODULE;

(xxvii) claims the benefit of and priority to U.S. Provisional Patent Application Ser. No. 61/091,642, filed Aug. 25, 2008 by Dallas W. Meyer for A LOW COST, HIGH RELIABILITY SOLAR PANEL;

(xxviii) claims the benefit of and priority to U.S. Provisional Patent Application Ser. No. 61/101,344, filed Sep. 30, 2008 by Dallas W. Meyer for A LARGE AREA LOW COST SOLAR MODULE; and

(xxix) claims the benefit of and priority to U.S. Provisional Patent Application Ser. No. 61/111,239, filed Nov. 4, 2008 by Dallas W. Meyer for ENVIRONMENTAL ROBUST ENHANCEMENTS TO RAIS;

(xxx) claims the benefit of and priority to U.S. Provisional Patent Application Ser. No. 61/042,629, filed Apr. 4, 2008 by Dallas W. Meyer for REDUNDANT ARRAY OF SOLAR;

(xxxi) claims the benefit of and priority to U.S. Provisional Patent Application Ser. No. 61/045,229, filed Apr. 16, 2008 by Dallas W. Meyer for A SAFE AND RELIABLE PHOTOVOLTAIC ARRAY;

The thirty-one (31) above-identified patent applications are hereby incorporated herein by reference in their entirety.

### BACKGROUND

1. Field of the Invention

The present invention relates generally to solar energy collection systems. More particularly, embodiments of the present invention relate to detachable louver systems for use with photovoltaic (“PV”) modules.

2. Related Technology

There are two main types of solar collectors, including silicon and thin films, commonly used in PV modules, the solar collectors commonly composed of PV cells. Silicon is currently the predominant technology, and can generally be implemented as monocrystalline or polycrystalline cells encapsulated behind a transparent glass front plate. Thin film technology is not as wide-spread as the silicon technology due to its reduced efficiency, but it is gaining in popularity due to its lower cost.

Currently, the solar energy industry is looking for ways to decrease the cost per unit of energy generated by PV modules. One approach to reducing cost per unit energy is to increase the exposure of the PV module to solar energy over time. For example, the orientation of the PV module relative to the sun can be adjusted throughout the day and/or throughout the year. Changing the orientation of the PV module relative to the sun throughout the day and/or year can require adjustable mounting systems that are costly and/or complicated with numerous parts prone to failure over the lifetime of the PV module.

Another approach to reducing the cost per unit energy of a PV module is to reduce the solar collector density of the PV module and concentrate solar energy incident on the PV module on the remaining solar collectors. Because conventional PV modules are typically very sensitive to and perform poorly under non-uniform illumination conditions, designing a concentrator system that uniformly concentrates light on the solar collectors can be difficult. The difficulty of designing and implementing such a concentrator system can add costs to the PV module that can counterbalance the savings from reducing the solar collector density.

Furthermore, concentrator systems that are integrated with the PV module can make the PV module more bulky and/or more difficult to handle and install. Additionally, integration of a concentrator system with the PV module may make it difficult to laminate and seal the solar collectors against moisture penetration.

The subject matter claimed herein is not limited to embodiments that solve any disadvantages or that operate only in environments such as those described above. Rather, this background is only provided to illustrate one exemplary technology area where some embodiments described herein may be practiced

### BRIEF SUMMARY OF SOME EXAMPLE EMBODIMENTS

In general, example embodiments of the invention relate to detachable louver systems.

One example embodiment includes a detachable louver system comprising primary louvers and a frame. The primary louvers are arranged substantially parallel to each other and are configured to reflect light rays incident on the primary louvers onto PV areas of a PV module. The frame is configured to support the primary louvers and to removably couple the detachable louver system to the PV module.

Another example embodiment includes a PV system comprising a PV module and a detachable louver system removably coupled to the PV module. The PV module is configured to remain in a single orientation during operation throughout the year and comprises PV areas and a substantially transparent front plate. The PV areas are configured to convert the energy of light rays incident on the PV areas to electricity. The front plate is disposed on top of the PV areas and is configured to protect the PV areas from damage. The detachable louver system is configured to reflect light rays incident on the detachable louver system onto the PV areas and includes a plurality of primary louvers arranged substantially parallel to each other.

Yet another example embodiment includes a method of forming a louver. The method includes laminating one side of a sheet of substrate material with a reflective layer and cutting the sheet of substrate material to width. The substrate material can then be shaped into a plurality of louvers, with each of the louvers being cut from the sheet of substrate material in a continuous process.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIGS. 1A-1D disclose an example PV system, including a PV module and detachable louver system, in which some embodiments of the invention can be implemented;

FIGS. 2A-2F disclose some example cross-sections of primary louvers that can be included in the detachable louver system of FIGS. 1A-1D;

FIGS. 3A and 3B disclose an example detachable louver system that is reversible between two configurations;

FIGS. 4A and 4B disclose an example non-reversible detachable louver system;

FIGS. 5A-5C disclose an example detachable louver system that includes secondary louvers and central reflectors;

FIG. 6A discloses a flat sheet of substrate material and a pattern that can be applied to the flat sheet of substrate material to form a plurality of primary louvers from the flat sheet of substrate material using a cutting and stamping method;

FIG. 6B discloses a side view of primary louvers that can be formed from the flat sheet of substrate material of FIG. 6A;

FIG. 6C discloses a front view of one of the primary louvers of FIG. 6B;

FIG. 6D discloses a central reflector that can be employed with the primary louvers of FIGS. 6B and 6C and that can rotatably support adjustable secondary louvers;

FIG. 7 discloses an example detachable louver system that includes adjustable secondary louvers;

FIGS. 8A-8C disclose an adjustable secondary louver comprising a thermally distortable substrate;

FIGS. 9A-9C disclose a perimeter louver that can be employed in detachable louver systems according to embodiments of the invention;

FIG. 10A discloses an example of a method of continuously roll-forming louvers and central reflectors;

FIG. 10B discloses an example primary louver that can be formed according to the method of FIG. 10A;

FIGS. 11A and 11B disclose a detachable louver system configured to add a transverse component to the angle of reflection of light rays incident on the detachable louver system;

FIGS. 11C and 11D disclose example paths of light rays incident on a detachable louver system that does not add a transverse component to the angle of reflection of light rays incident on the detachable louver system;

FIGS. 11E and 11F disclose example paths of light rays incident on the detachable louver system of FIGS. 11A and 11B;

FIGS. 12A-12D disclose an example PV system that includes quasi-trapezoidal shaped PV cells and primary louvers with corrugations configured to reflect light rays that would otherwise impinge on non-PV areas between adjacent photosensitive cells onto the PV cells;

FIGS. 13A-13D disclose four sets of louver configurations of varying normalized heights, each of the four sets designed for use with PV modules having one of four PV area densities;

FIG. 14 discloses 6-month figure of merit calculations for six different sets of louver configurations of varying normalized heights; and

FIG. 15 discloses 5-day figure of merit calculations for a set of five louver configurations all designed for use with PV modules having a 50% PV area density.

### DETAILED DESCRIPTION OF EXAMPLE EMBODIMENTS

Embodiments of the invention are generally directed to a detachable louver system used to concentrate solar energy on a PV module. Some example embodiments include a detachable louver system that can be attached to and/or removed from a PV module by a single person. In some cases, the detachable louver system can be rotated between two or more different positions during the year to maximize the amount of energy collected by the PV module throughout the year while the PV module remains in a single position throughout the year. In some embodiments, implementation of a detachable louver system can facilitate the use of PV modules having relatively low PV area densities while generating substantially the same amount of energy as conventional higher density modules, resulting in a relatively lower cost per unit energy.

### I. Example Operating Environment

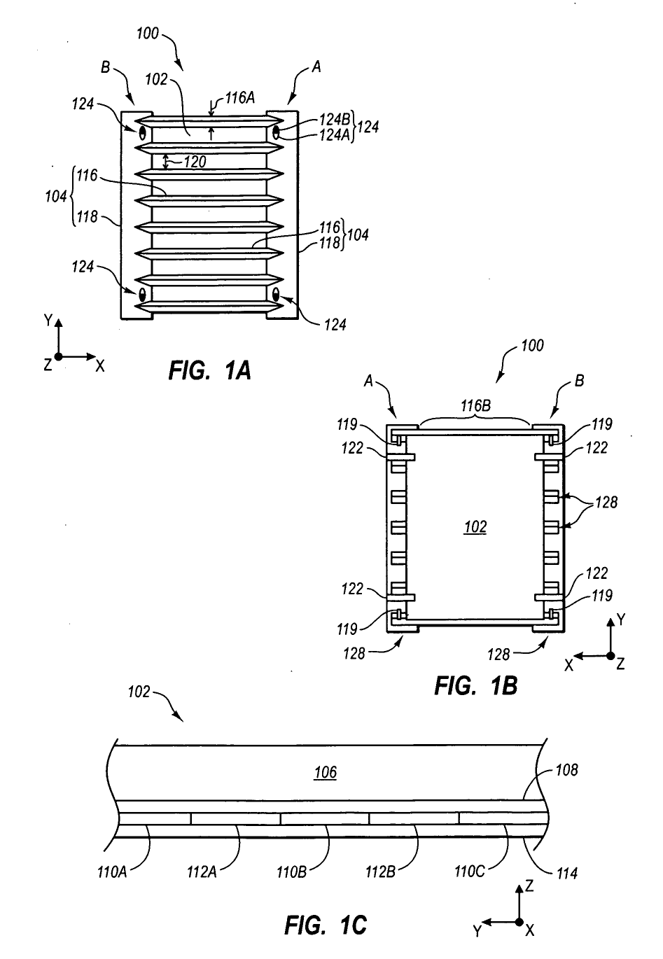

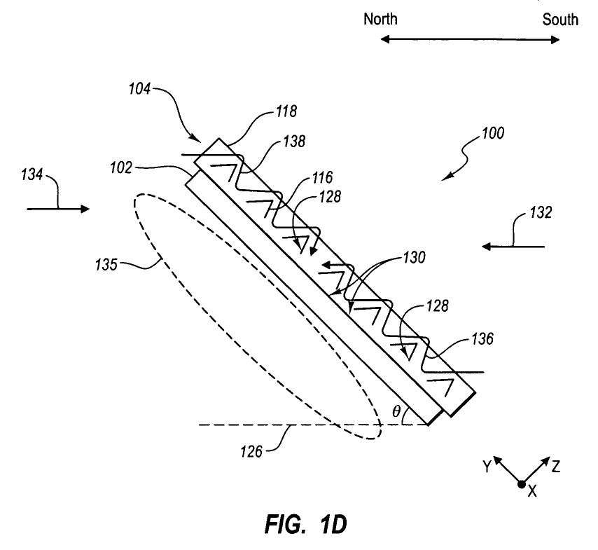

Reference is first made to FIGS. 1A and 1B, which depict one possible environment wherein embodiments of the present invention can be practiced. Particularly, FIGS. 1A and 1B show a front view and a back view, respectively, of a PV system, designated generally at 100. The PV system 100 generally includes one or more PV modules 102 and one or more corresponding detachable louver systems 104.

A. General Aspects of Some PV Modules

With additional reference to FIG. 1C, a simplified cross-sectional side view of the example PV module 102 is provided. As shown in FIG. 1C, the PV module 102 may comprise, for example, a front plate 106, an adhesive layer 108 disposed beneath the front plate 106, a plurality of PV areas 110A-110C interposed among a plurality of spacers 112A-112B and disposed beneath the adhesive layer 108, and a buffer layer 114 disposed beneath the PV areas 110A-110C.

The front plate 106 may comprise a substantially transparent substrate, such as glass, plastic, or the like, upon which the other layers of the PV module 102 can be grown or otherwise placed during manufacture of the PV module 102. The front plate 106 may protect the PV areas 110A-110C from damage due to environmental factors, including moisture, wind, and the like. The substantially transparent nature of the front plate 106 can allow solar energy in the form of electromagnetic radiation from the sun, e.g. light rays, to penetrate through the front plate 106 and impinge upon the PV areas 110A-110C. Alternately or additionally, the front plate 106 can provide structural support to the PV areas 110A-110C

The adhesive layer 108 can couple the front plate 106 to the PV areas 110A-110C and may comprise ethylene-vinyl acetate (“EVA”), or other suitable adhesive. In some embodiments, the adhesive layer 108 can be 2-4 mils thick, or more or less than 2-4 mils thick in other embodiments. The adhesive layer 108 may be substantially transparent to solar radiation to allow light rays to reach the PV areas 110A-110C. Alternately or additionally, the adhesive layer 108 can be treated to substantially prevent ultraviolet (“UV”) damage and/or yellowing of the adhesive layer 108.

The buffer layer 114 can couple a backsheet (not shown) of the PV module 102 to the PV areas 110A-110C and can electrically insulate the PV areas 110A-110C from the backsheet. As such, the buffer layer 114 can comprise an adhesive such as EVA, an electrically insulating material such as polyethylene terephthalate (“PET”), or the like or any combination thereof. In some embodiments, the buffer layer 114 can be about 3 mils thick, or more or less than 3 mils thick.

Generally speaking, the PV areas 110A-110C convert solar energy into electricity by the photovoltaic effect. Each of the PV areas 110A-110C may comprise a plurality of PV cells arranged in a row. Although not required, in some embodiments all of the PV cells in each row are connected to each other in parallel, while all of the rows are connected to each other in series. Each of the PV cells making up PV areas 110A-110C may comprise a monocrystalline solar cell or a polycrystalline solar cell. Alternately or additionally, each of PV areas 110A-110C can comprise a strip of PV material, such as amorphous silicon or CIGS, in place of individual PV cells. The PV areas 110A-110C can include silicon, copper, indium, gallium, selenide, or the like or any combination thereof.

Each of the spacers 112A-112B may comprise an electrically conductive material, such as aluminum, copper, or the like. Further, in some embodiments, the spacers 112A-112B are implemented in the electrical interconnections between adjacent PV areas 110A-110C.

B. General Aspects of Some Detachable Louver Systems

Returning to FIG. 1A, aspects of the detachable louver system 104 are disclosed. As shown in FIG. 1A, the detachable louver system 104 may comprise, for example, a plurality of primary louvers 116 arranged substantially parallel to each other, and a frame 118 supporting the plurality of primary louvers 116. In some embodiments, foam tape 119 or other adhesive or fasteners can be applied in various locations, e.g., the four corners of the detachable louver system 104, to secure the primary louvers 116 to the frame 118. Further, the frame 118 may be configured to removably couple the detachable louver system 104 to the PV module 102 and can include, for instance, coupling means as will be described below.

Generally speaking, the primary louvers 116 are configured to reflect solar energy incident on the primary louvers 116 onto the PV areas 110A-110C (FIG. 1C). As such, in some embodiments, the width 116A of each primary louver 116 may be substantially equal to the width of each spacer 112A-112B (FIG. 1C), while the width 120 of each gap between adjacent primary louvers 116 may be substantially equal to the width of each PV area 110A-110C. Accordingly, the detachable louver system 104 can be configured to detachably couple to the PV module 102 such that each of the primary louvers 116 is positioned above a corresponding spacer 112A-112B, while each of the gaps between adjacent primary louvers 116 is positioned above a corresponding PV area 110A-110C. Such a configuration can allow solar energy incident on the primary louvers 116 to be reflected onto the PV areas 110A-110C.

Optionally, as shown in FIGS. 1A and 1B, means 122, 124 for detachably coupling (“coupling means 122, 124”) the detachable louver system 104 to the PV module 102 and for aligning the detachable louver system 104 with the PV module 102 can be included on one or both of the detachable louver system 104 and/or the PV module 102. The coupling means 122, 124 can, e.g. secure the detachable louver system 104 to the PV module 102 and/or ensure proper alignment of the detachable louver system 104 with the PV module 102 when the detachable louver system 104 is secured to the PV module 102.

In some embodiments, the coupling means 122, 124 can include one or more spring clips 122 attached near the four corners of the detachable louver system 104, as shown in FIG. 1B. The one or more spring clips 122 can be movable between an open position (not shown) and a closed position (as shown in FIG. 1B). In the closed position, the one or more spring clips 122 can engage edges of the PV module 102 to secure the detachable louver system 104 to the PV module 102. In the open position, the one or more spring clips 122 do not engage the PV module 102, allowing the detachable louver system 104 to be installed, removed, rotated, or the like.

Alternately or additionally, as shown in FIG. 1A, the coupling means 122, 124 can include one or more slotted holes 124A formed in the detachable louver system 104, and one or more pins 124B attached to the PV module 102. The slotted holes 124A and pins 124B can generally be positioned such that alignment and insertion of the pins 124B into the slotted holes 124A results in alignment of the primary louvers 116 with the spacers 112A-112B and in alignment of the gaps between the primary louvers 116 with the PV areas 110A-110C.

Spring clips 122, slotted holes 124A, and pins 124B are one example of coupling means 122, 124 that can be implemented to removably couple and/or align the detachable louver system 104 to the PV module 102. In other embodiments, the coupling means 122, 124 can be disposed in different positions on the detachable louver system 104 and/or PV module 102. Alternately or additionally, the coupling means 122, 124 can include one or more other clips, slots, pins, latches, screws, bolts, nuts, adhesives, fasteners, or the like or any combination thereof.

With additional reference to FIG. 1D, the detachable louver system 104 and PV module 102 can be used in aligned or non-aligned orientations to the sun. In both orientations, the primary louvers 116 can generally be aligned east to west. Further, in both orientations, the PV module 102 and detachable louver system 104 can be positioned such that the front of the PV module 102 and detachable louver system 104 generally faces south for installation sites in the Northern Hemisphere as shown in FIG. 1D, or generally faces north for installation sites in the Southern Hemisphere (not shown).

The difference between an orientation aligned to the sun (“aligned orientation”) and an orientation not aligned to the sun (“non-aligned orientation”) relates to an angle θ of the PV module 102—and detachable louver system 104—relative to a horizontal reference plane 126 at the installation site. In particular, in an aligned orientation, the value of the angle θ can be approximately equal to the latitude of the installation site of the PV system 100, ±3 degrees. In contrast, in a non-aligned orientation, the value of the angle θ can be at least 3 degrees greater or less than the latitude of the installation site. When the PV module 102 is aligned at an angle θ that is substantially equal to the latitude of the installation site, incoming light rays from the sun can be substantially normal to the surface of the PV module 102 at midday at or around the spring and fall equinoxes.

In some embodiments, the exact configuration of the detachable louver system 104 can differ depending on whether the PV module 102 is in an aligned or non-aligned orientation. For example, if the PV module 102 is in an aligned orientation, the detachable louver system 104 can include primary louvers 116 that are symmetrically shaped and the detachable louver system 104 can remain stationary throughout the year. Alternately, if the PV module 102 is in an aligned orientation, the detachable louver system 104 can include primary louvers 116 that are asymmetrically shaped and the detachable louver system 104 can be rotated two times per year. Alternately, in a non-aligned orientation, the detachable louver system 104 can include primary louvers 116 that are asymmetrically shaped and the detachable louver system 104 can remain stationary throughout the year.

With combined reference to FIGS. 1B and 1D, the detachable louver system 104 can further include a plurality of air vents 128 integrally formed in the primary louvers 116 and/or the frame 118. FIG. 1D depicts a cross-sectional side view of the PV system 100 in an aligned orientation. In this and other embodiments, the detachable louver system 104 can be removably coupled to the PV module 102 such that gaps 130 are present between the base of each primary louver 116 and the PV module 102.

FIG. 1D includes two arrows 132 and 134 that are generally representative of wind. In particular, the arrow 132 indicates wind generally blowing towards the front of the PV system 100. The arrow 134 indicates wind generally blowing towards the back of the PV system 100.

In the example of FIG. 1D, the wind 132 can force air to enter the vents 128 of primary louvers 116 via gaps 130. The forced air can then move along the primary louver 116 vents 128 toward either end A or B (FIG. 1B) of the primary louvers 116 where the forced air can exit the vents 128 from the back of ends A and/or B of the primary louvers 116. The forcing of air from the front of the PV system 100 into the vents 128 through gaps 130 and then out the back of ends A and/or B of the primary louvers 116 can create a high pressure-to-low pressure gradient from the front to the back of the PV system 100 by creating a low pressure area 135 at the back of the PV system 100.

Alternately or additionally, the wind 132 can pass between the primary louvers 116 and PV module 102 via gaps 130. Alternately or additionally, the wind 134 can force air to enter primary louver 116 vents 128 via the exposed ends A and/or B of the primary louvers 116. In this example, the forced air can then move along the primary louver 116 vents 128 from the ends A and/or B towards the intermediate areas 116B (FIG. 1B) of the primary louvers 116, where the air can be forced out of vents 128 through gaps 130. In these and other embodiments, the passage of air through gaps 130 can substantially prevent debris from accumulating on the detachable louver system 104 and/or PV module 102 by dislodging any debris present on the detachable louver system 104 and/or PV module 102.

In some embodiments, the wind 132 can generate a laminar flow 136 across the top of the primary louvers 116. Alternately or additionally, the wind 134 can generate a laminar flow 138 across the top of primary louvers 116 in the opposite direction as laminar flow 136. The laminar flows 136, 138 and/or other air flow facilitated by primary louver 116 vents 128, frame 118 vents 128, and/or gaps 130 can facilitate heat dissipation from the PV module 102.

### II. Examples of Some Detachable Louver Systems

In some embodiments, the detachable louver system 104 can incorporate or include one or more additional aspects or features. Briefly, for instance, a cross-sectional shape of each of the primary louvers 116 can be one or more of: symmetric, asymmetric, and/or triangular and can include one or more linear, curved, or curvilinear sides, or the like. Alternately or additionally, the detachable louver system 104 can be reversible between two configurations relative to the PV module 102 to maximize the amount of energy generated by the PV module 102 during two or more different times of the year. Alternately or additionally, the detachable louver system 104 can include one or more central reflectors, one or more secondary louvers, and/or one or more perimeter louvers. Alternately or additionally, a cross-sectional shape and/or height of each of the primary louvers 116 can be determined by iterating and optimizing on specific and defined degrees of freedom along the primary louvers 116 to maximize the amount of energy generated by the PV module 102 over the course of a year in association with the detachable louver system 104.

A. Primary Louvers

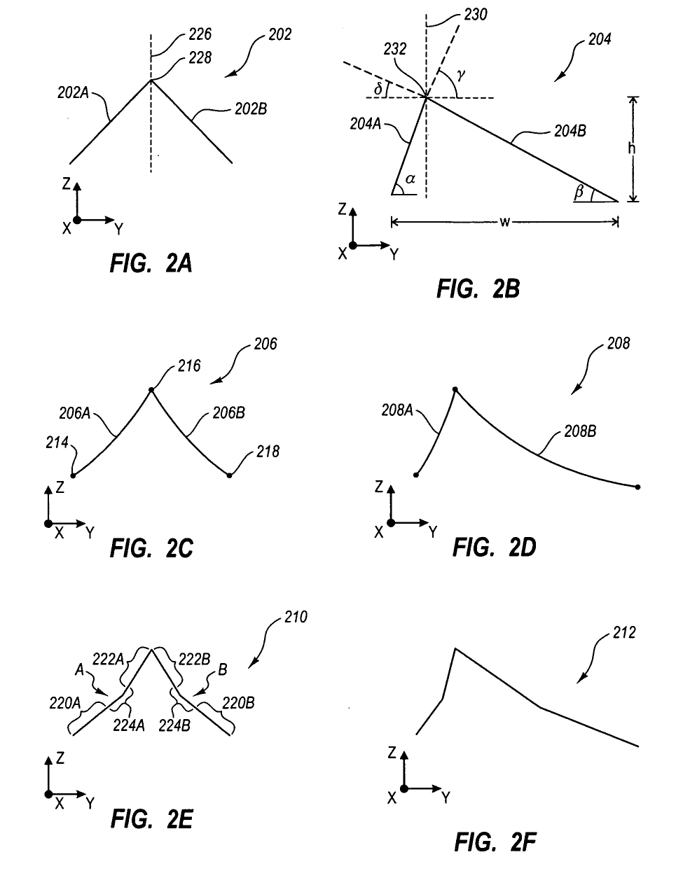

With reference to FIGS. 2A-2F, various primary louvers 202-212 having different cross-sectional shapes are disclosed. Each of the primary louvers 116 of FIGS. 1A-1D may have a cross-section corresponding to one or more of the cross-sections of the primary louvers 202-212 illustrated in FIGS. 2A-2F. As such, each of the primary louvers 202-212 depicted in FIGS. 2A-2F can be implemented in a detachable louver system and positioned above a PV module front plate that is substantially parallel to the arbitrarily defined x-y plane.

Each of FIGS. 2A and 2B depict primary louvers 202, 204 that have cross-sections that are substantially triangular in shape. The primary louvers 202, 204 have sides 202A-202B and 204A-204B that are substantially linear. Additionally, the primary louvers 202, 204 are open at the base of the substantially triangular cross-section. In other embodiments, the primary louvers 202, 204 can have cross-sections that are closed triangular shapes.

FIGS. 2C and 2D depict primary louvers 206, 208 that have cross-sections that are quasi-triangular in shape. A “quasi-triangular shape” generally refers to a shape having three vertices, such as vertices 214, 216 and 218 of primary louver 206, and one or more non-linear sides. The primary louvers 206, 208 can be open at the base of the quasi-triangular cross-sectional shape, as shown, or the primary louvers 206, 208 can be closed at the base. The primary louvers 206 and 208 have sides 206A-206B and 208A-208B that are curved. In a plane parallel to the arbitrarily defined y-z plane, each of the curved sides 206A-206B and 208A-208B can be defined by one or more of: a segment of a circle, a segment of a parabola, a segment of an ellipse, a segment of an oval, a segment of a hyperbolic curve, a segment of a logarithmic curve, a segment of an exponential curve, or the like or any combination thereof.

FIGS. 2E and 2F also depict primary louvers 210, 212 that have cross-sections that are quasi-triangular in shape. Similar to the primary louvers 206, 208, the primary louvers 210, 212 can be open at the base of the quasi-triangular cross-sectional shape, as shown, or the primary louvers 210, 212 can be closed at the base. In contrast to primary louvers 206, 208, however, primary louvers 210, 212 have sides A and B that are curvilinear. A “curvilinear” side refers to a side defined by a combination of one or more curved segments and one or more line segments. For instance, side A of primary louver 210 includes two line segments 220A and 222A and a curved segment 224A, while side B of primary louver 210 also includes two line segments 220B and 222B and a curved segment 224B.

Returning to FIG. 2A, the primary louver 202 may be substantially symmetric, meaning the primary louver 202 has a cross-section that is substantially symmetric. A primary louver has a cross-section that is substantially symmetric if the cross-section is substantially symmetric about a reference plane that is substantially perpendicular to the base of the primary louver—and to a corresponding PV module to which the primary louver is mounted—and that intersects the apex of the primary louver. For instance, the primary louver 202 is substantially symmetric about reference plane 226 because reference plane 226 is substantially perpendicular to the base of the primary louver 202—and to a corresponding PV module—and because reference plane 226 intersects the apex 228 of the primary louver 202. Although reference planes are not shown in FIGS. 2C and 2E, the primary louvers 206 and 210 of FIGS. 2C and 2E may also be symmetric.

In contrast, the primary louver 204 of FIG. 2B may be substantially asymmetric, meaning the primary louver 204 has a cross-section that is substantially asymmetric. A primary louver has a cross-section that is substantially asymmetric if the cross-section is substantially asymmetric about a reference plane that is substantially perpendicular to the base of the primary louver—and to a corresponding PV module to which the primary louver is mounted—and that intersects the apex of the primary louver. For instance, the primary louver 204 is substantially asymmetric about reference plane 230 because reference plane 230 is substantially perpendicular to the base of the primary louver 204—and to a corresponding PV module—and because reference plane 230 intersects the apex 232 of the primary louver 204. Although reference planes are not shown in FIGS. 2D and 2F, the primary louvers 208 and 212 of FIGS. 2D and 2F can also be asymmetric.

In some embodiments, substantially symmetric primary louvers can be used in aligned and non-reversible detachable louver systems, while substantially asymmetric primary louvers can be used in non-aligned and non-reversible detachable louver systems. Alternately or additionally, substantially asymmetric primary louvers can be used in aligned and reversible detachable louver systems. Other combinations are also contemplated within the scope of the invention, including the use of substantially symmetric primary louvers in non-aligned and/or reversible detachable louver systems, for example. Various example detachable louver systems will be disclosed below that incorporate symmetric and/or asymmetric primary louvers.

Accordingly, embodiments of the invention include primary louvers having substantially triangular or quasi-triangular cross-sectional shapes, or other cross-sectional shapes as well, such as energy-optimized cross-sectional shapes determined by iterating over a number of degrees of freedom of a primary louver to maximize the energy collected over a period of time. Alternately or additionally, the cross-sectional shapes of the primary louvers can be open or closed at the base of the primary louvers. Alternately or additionally, the primary louvers can have cross-sectional shapes with linear, curved, and/or curvilinear sides.

In some embodiments, the primary louvers implemented in a detachable louver system can be shaped to maximize the amount of light that the detachable louver system allows to impinge, either directly or via reflection off the detachable louver system, on PV areas of the corresponding PV module throughout the year. Methods for determining a primary louver shape to maximize the amount of impinging light will be discussed in greater detail below.

Further, various parameters can be used in determining the primary louver shape that maximizes the amount of impinging light, the various parameters also describing the shape of the primary louver. For instance, with reference to the primary louver 204 of FIG. 2B, the parameters can include: (1) the height h of the primary louver 204 from its base to its apex 232, (2) the angles α and β at the base of the two sides 204A, 204B relative to the x-y plane, (3) the angles γ and δ at the vertex 232 of the two sides 204B, 204A relative to the x-y plane, which may be different than, respectively, the angles α and β in, e.g. FIGS. 2C-2F, and/or (4) the width w of the primary louver 204 at the base of the primary louver 204. Similar and/or different parameters can be used to describe the shapes of primary louvers 202 and 206-212.

B. First Example Detachable Louver System

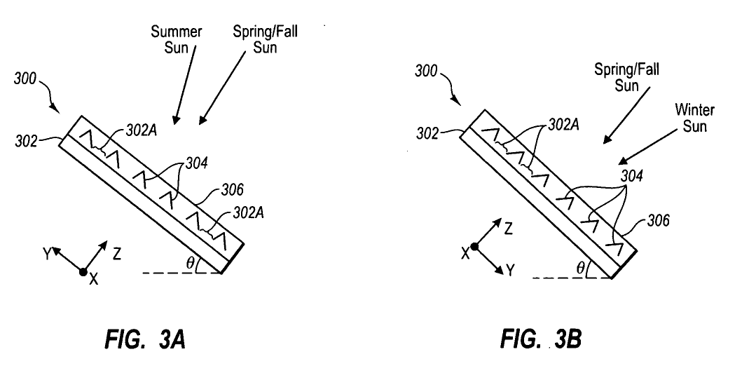

Turning next to FIGS. 3A and 3B, a first example detachable louver system 300 is disclosed that may correspond to the detachable louver system 104 of FIGS. 1A-1D and that is reversible. FIGS. 3A and 3B depict, respectively, cross-sectional side views of the detachable louver system 300 in a first configuration and a second configuration. FIGS. 3A and 3B further depict a corresponding PV module 302 to which the detachable louver system 300 can be removably coupled. In some embodiments, the PV module 302 and detachable louver system 300 can be installed in an aligned orientation such that incoming light rays from the sun are substantially normal to the PV module 302 at about midday around the spring equinox and the fall equinox. Alternately, non-aligned orientations are also contemplated.

The detachable louver system 300 can include a plurality of primary louvers 304 and a frame 306. Each of the primary louvers 304 can be asymmetric and can have a substantially triangular cross-sectional shape. Alternately, the primary louvers 304 can have quasi-triangular cross-sectional shapes with curved and/or curvilinear sides. The cross-sectional shape of the primary louvers 304 can be configured to maximize the energy collected by the PV module 302 during a first time of year when the detachable louver system is in the first configuration of FIG. 3A, while maximizing the energy collected by the PV module 302 during a second time of year when the detachable louver system is in the second configuration of FIG. 3B.

The first configuration of FIG. 3A may comprise a “summer” configuration employed from about the spring equinox to about the fall equinox, while the second configuration of FIG. 3B may comprise a “winter” configuration employed from about the fall equinox to about the spring equinox. In this example, during the time period from the spring equinox to the fall equinox, light rays from the sun typically arrive from more directly overhead than during the time period from the fall equinox to the spring equinox. Accordingly, during the time period from the spring equinox to the fall equinox, the “summer” configuration of FIG. 3A may be more effective at allowing light rays to impinge—either directly and/or via reflection—on PV areas 302A of the PV module 302 than the “winter” configuration of FIG. 3B. Analogously, during the time period from the fall equinox to the spring equinox, the “winter” configuration of FIG. 3B may be more effective at allowing light rays to impinge on the PV areas 302A than the “summer” configuration of FIG. 3A.

In this and other examples, the detachable louver system 300 can be changed from one orientation to the other at the spring equinox and the fall equinox, or within about 3 weeks, respectively, of the spring equinox or the fall equinox. Alternately or additionally, each of the first and second configurations of FIGS. 3A and 3B may be employed to cover time periods other than from the spring equinox to the fall equinox and vice versa, in which case the detachable louver system 300 can be changed from one orientation to the other at times other than at or around the spring equinox and the fall equinox.

C. Second Example Detachable Louver System

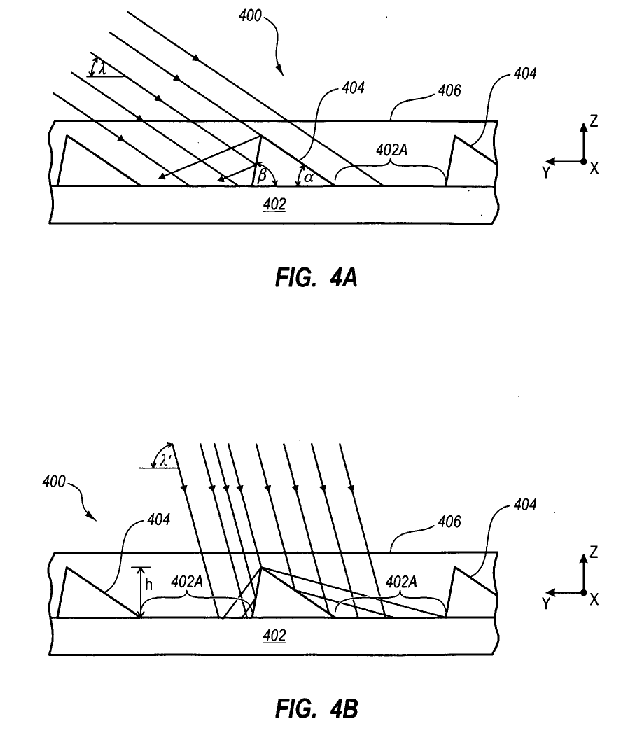

Turning next to FIGS. 4A and 4B, a second example detachable louver system 400 is disclosed that may correspond to the detachable louver system 104 of FIGS. 1A-1D and that is not reversible. FIGS. 4A and 4B depict, respectively, cross-sectional side views of the detachable louver system 400 at a first time of year, such as at the winter solstice, and at a second time of year, such as at the summer solstice. As shown, the incoming light rays in the summer (FIG. 4B) come from more directly overhead than the incoming light rays in the winter (FIG. 4A).

FIGS. 4A and 4B further depict a corresponding PV module 402 to which the detachable louver system 400 can be removably coupled. In some embodiments, the PV module 402 and detachable louver system 400 can be installed in a non-aligned orientation, such as parallel to a horizontal surface at a non-equatorial installation site. Alternately, aligned orientations are contemplated.

The detachable louver system 400 can include a plurality of primary louvers 404 and a frame 406. Each of the primary louvers 404 can be substantially asymmetric, similar to the primary louvers 304 of FIGS. 3A and 3B. The cross-sectional shape of the primary louvers 404 can be configured to maximize the energy collected by the PV module 402 throughout the year without rotating the detachable louver system 400 between “summer” and “winter” configurations. For instance, the primary louvers 404 may be configured to maximize the amount of light impinging on PV areas 402A of the PV module 402 throughout the year. In some embodiments, however, the non-aligned detachable louver system 400 of FIGS. 4A and 4B may be less efficient at maximizing the amount of light impinging on PV areas 402A of the PV module 402 throughout the year than a similarly dimensioned aligned and reversible detachable louver system 300 is at maximizing the amount of light impinging on PV areas 302A of the PV module 302 of FIGS. 3A and 3B throughout the year.

D. Third Example Detachable Louver System

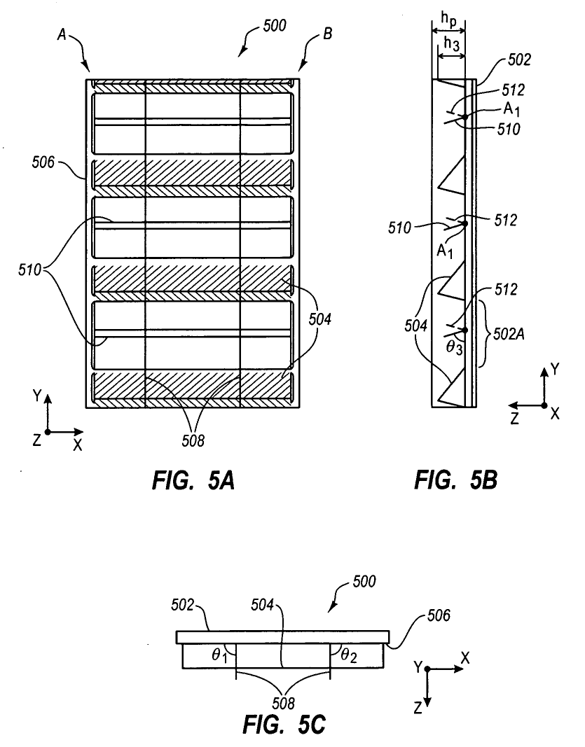

Turning next to FIGS. 5A-5C, a third example detachable louver system 500 is disclosed that may correspond to the detachable louver system 104 of FIGS. 1A-1D. FIGS. 5A-5C depict, respectively, a front view, a cross-sectional side view, and an end view of the detachable louver system 500. FIGS. 5A-5C further depict a PV module 502 to which the detachable louver system 500 can be removably coupled.

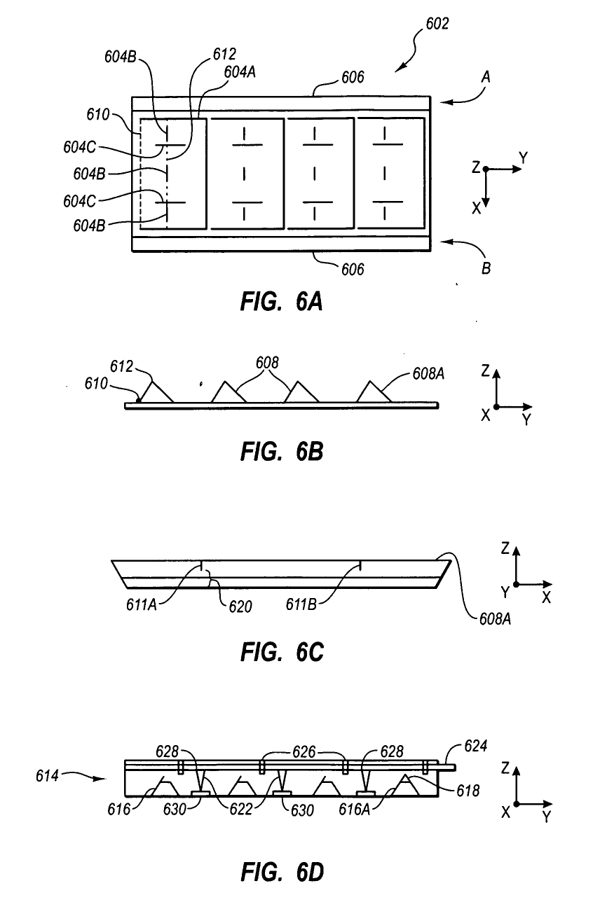

As shown, the detachable louver system 500 can include a plurality of primary louvers 504 and a frame 506. In some embodiments, the primary louvers 504 and frame 506 can be formed from a single sheet of metal or other material by cutting and stamping the sheet of metal, as will be explained below with respect to FIGS. 6A-6D. The detachable louver system 500 can optionally include one or more central reflectors 508, a plurality of secondary louvers 510, or both. One or both of the central reflectors 508 and secondary louvers 510 can be supported by the frame 506.

E. Central Reflectors

The central reflectors 508 can be arranged substantially perpendicular to the primary louvers 504. The central reflectors 508 can provide support for the primary louvers 504. Alternately or additionally, when perimeter louvers are implemented along the sides A and B of the detachable louver system 500, the central reflectors 508 can reflect light rays incident on the central reflectors 508 from the perimeter louvers or directly from the sun onto PV areas 502A (FIG. 5B) of the PV module 502. Perimeter louvers will be discussed in greater detail below.

As best seen in FIG. 5C, each of central reflectors 508 may comprise a substantially planar piece of metal or other material. Each of the central reflectors 508 may be arranged at an angle θ₁ or θ₂ relative to the plane of the PV module 502. The angles θ₁ and θ₂ can be equal to or different from each other. In the embodiment of FIG. 5C, both of the angles θ₁ and θ₂ can be substantially equal to 90 degrees. In other embodiments, however, one or both of the angles θ₁ and θ₂ can be greater or less than 90 degrees.

In some embodiments, slots can be formed at predetermined locations in the primary louvers 504 and/or secondary louvers 510 to accommodate the central reflectors 508. Alternately or additionally, slots can be formed at predetermined locations in the central reflectors 508 to accommodate the primary louvers 504 and/or secondary louvers 510. For instance, FIGS. 6A-6D disclose a method of forming a detachable louver system with slots formed in both the primary louvers and the central reflectors.

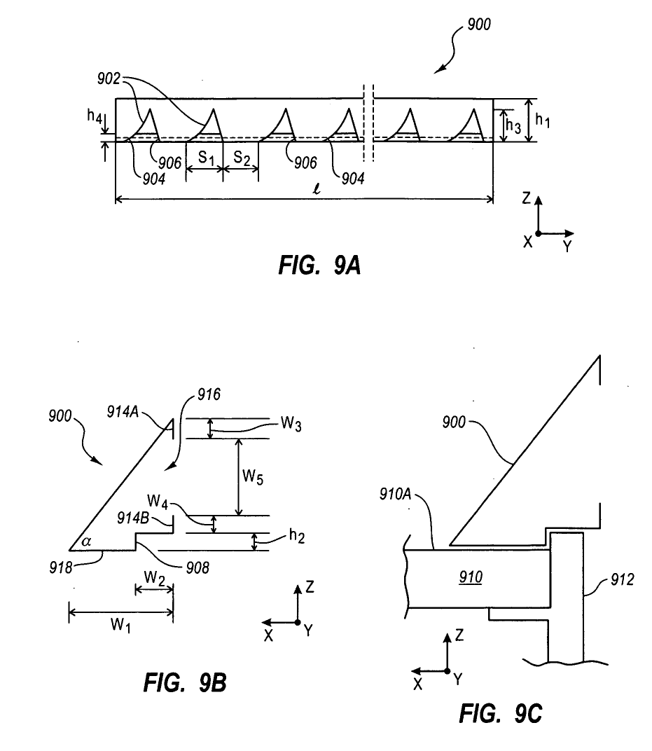

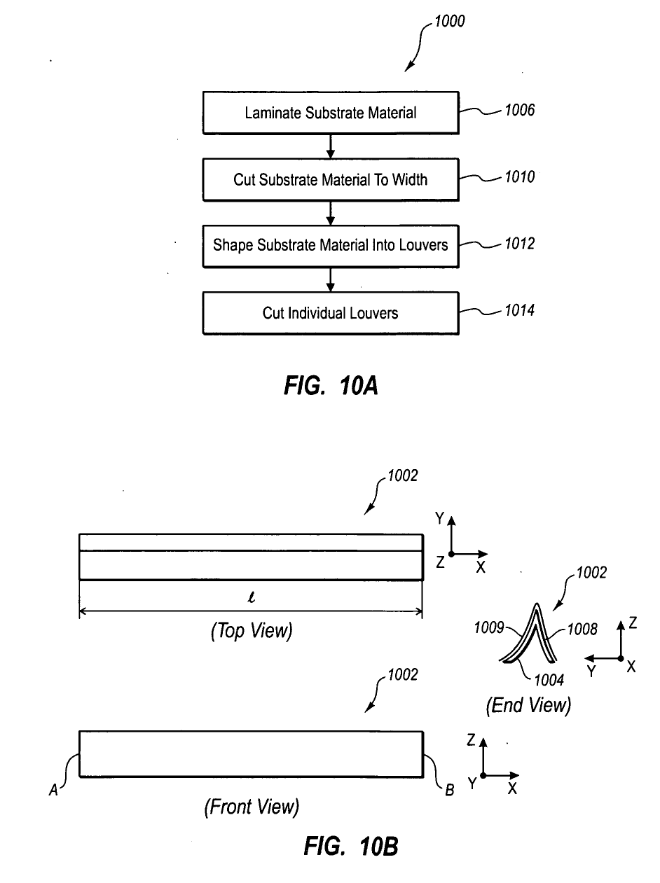

The method of FIGS. 6A-6D can begin in FIG. 6A with a flat sheet 602 of louver stock. The flat sheet 602 of louver stock may comprise, for example, sheet metal, sheet plastic, or the like. A reflective layer (not shown) can be applied to the front surface of the flat sheet 602 by lamination or any other known or unknown process. Aspects of some example reflective layers that can be applied to flat sheets of louver stock such as flat sheet 602 will be discussed in greater detail below with respect to FIGS. 9B and 10B.

After applying the reflective layer to the flat sheet 602, a pattern 604, comprising pattern elements 604A-604C, can be repeatedly cut in the flat sheet 602. The pattern 604 can be laser cut, die cut, or the like. Each pattern element 604A of the pattern 604 can correspond to what will eventually be a primary louver. Pattern elements 604B can form the basis for a fold line at the apex of each primary louver formed from pattern element 604A. Each of pattern elements 604C can comprise a slot for accommodating all or a portion of a central reflector.

Optionally, the edges A and B of the flat sheet 602 can be folded to form a reinforced frame 606 to support the primary louvers eventually formed from the pattern elements 604A. Alternately or additionally, the folded edges A and B can each form a perimeter louver.

As best seen in the side view of FIG. 6B, after cutting the pattern 604 into the flat sheet 602, primary louvers 608 can then be formed by stamping the flat sheet 602. In this example, stamping may include folding each pattern element 604A upwards to form a first fold line 610 where the pattern element 604A joins the rest of flat sheet 602 and/or bending each pattern element 604A downwards at pattern elements 604B to form a second fold line 612 that is substantially collinear with pattern elements 604B.

Each of the pattern elements 604C can comprise a slot 611B or 611A for accommodating all or a portion of a central reflector, as best seen in the end view of FIG. 6C. A side view of an example central reflector 614 that may be partially accommodated by slots 611B, 611A is provided in FIG. 6D.

The central reflector 614 can be formed in a separate process than the frame 606 and primary louvers 608 in some embodiments. As seen in FIG. 6D, the central reflector 614 can include a first plurality of notches 616 for accommodating all or a portion of the primary louvers 608. Further, for purposes of this discussion, the primary louvers 608 can include a primary louver 608A (FIGS. 6B and 6C) and the first notches 616 can include a first notch 616A (FIG. 6D).

In this example, to assemble the central reflector 614 to the frame 606 and primary louvers 608, the central reflector 614 can be positioned substantially perpendicular to the primary louvers 608. The central reflector 614 can be positioned such that the first notch 616A is aligned to receive primary louver 608A at the slot 611B (or 611A), and the slot 611B (or 611A) is aligned to receive central reflector 614 at the first notch 616A. Once assembled, the slot 611B (or 611A) can accommodate a portion 618 of the central reflector 614 that is immediately above the first notch 616A, and the first notch 616A can accommodate a portion 620 of the primary louver 608A that is immediately below the slot 611B.

Optionally, as seen in FIG. 6D, the central reflector 614 can be configured to adjustably support a plurality of secondary louvers (not shown). As such, the central reflector 614 can include a second plurality of notches 622, an adjust lever 624, one or more holding slots 626, one or more fasteners 628, and one or more locking tabs 630. The second notches 622 can accommodate all or a portion of the secondary louvers. The holding slots 626 can secure the adjust lever 624 to the central reflector 614 while allowing the adjust lever 624 to move axially through the holding slots 626. The fasteners 628 can secure the secondary louvers to the adjust lever 624. The adjust lever 624 can adjust the secondary louvers between two or more different positions. The locking tabs 630 can hold the base of the secondary louvers in place. Adjustable secondary louvers will be discussed in greater detail below.

F. Secondary Louvers

Returning to FIGS. 5A-5C, the secondary louvers 510 can be arranged substantially parallel to and interposed between the primary louvers 504. The secondary louvers 510 can be supported by the frame 506 and/or central reflectors 508. Further, the secondary louvers 510 can reflect light rays incident on the secondary louvers 510 onto the PV areas 502A of PV module 502. The light rays incident on the secondary louvers 510 can come directly from the sun, and/or the light rays can be reflected by the primary louvers 504 before being reflected by the secondary louvers 510 onto the PV areas 502A. In some embodiments of the invention, the primary louvers 504 can be substantially positioned over gaps between the PV areas 502A while the secondary louvers 510 can be substantially positioned over the PV areas 502A.

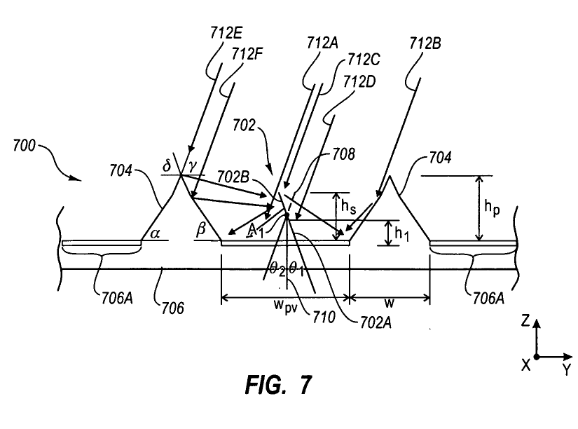

In some embodiments, the secondary louvers 510 can be fixed with respect to the primary louvers 504, while in other embodiments the secondary louvers 510 can be adjustable between at least two positions with respect to the primary louvers 504. For instance, FIG. 7 discloses a detachable louver system 700 that includes one or more adjustable secondary louvers 702 that may be supported by a frame (not shown). The detachable louver system 700 further includes one or more symmetric quasi-triangular primary louvers 704 having curvilinear sides, although the primary louvers may have other shapes in other embodiments. The detachable louver system 700 is shown attached to a PV module 706 having one or more PV areas 706A.

As shown in FIG. 7, each of primary louvers 704 may be characterized by a height hₚ of the primary louvers 704 above the PV module 706, a width w, and angles α, β, γ and δ. In this example, the height hₚ can be about 1.5 inches, the width w can be about 1.6 inches, the angles α and β can both be about 60 degrees and the angles γ and δ can both be about 67 degrees. Alternately or additionally, the values of the height hₚ, width w, and angles α, β, γ and δ can be greater than, less than, or equal to the values explicitly stated herein in other embodiments.

Each of the secondary louvers 702 may be characterized by a height hₛ of the secondary louvers 702 above the PV module 706. The height hₛ can be about 1.1 inches in some embodiments, although the height hₛ may be more or less than 1.1 inches in other embodiments. Further, the secondary louvers 702 can be positioned such that the base 702A of each secondary louver 702 is aligned along a midline of a corresponding PV area 706A. For instance, for a PV area 706A that has a width wₚᵥ that is two inches wide, the secondary louver 702 can be aligned with its base 702A running down the middle of the PV area 706A such that there is about one inch of PV area 706A on each side of the base 702A of the secondary louver 702. In other embodiments, the secondary louver 702 can be aligned with its base 702A at positions other than the midline of the PV area 706A and/or the PV area 706 can have a width wₚᵥ greater or less than two inches.

In addition, the secondary louvers 702 can be adjustable between at least the first position shown in FIG. 7, and a second position represented by reference plane 708. The secondary louvers 702 can be adjusted between the at least two positions at or around predetermined times of the year to maximize the amount of energy generated by the PV module 706 throughout the year. As will be explained in more detail below, the secondary louvers 702 can be adjusted between the at least two positions in a variety of ways, including through the use of a movable lever, by employing a thermal substrate to construct the secondary louvers 702, or the like or any combination thereof.

As shown in FIG. 7, an upper portion 702B of each secondary louver 702 can be rotatable about an axis A₁ running the length of the secondary louver 702, the axis A₁ being substantially parallel to the base 702A of the secondary louver 702. Further, the axis A₁ can be disposed at a height h₁ above the PV module 706. The height h₁ can be about 0.4 inches in some embodiments, or more or less than 0.4 inches in other embodiments.

In the first position shown in FIG. 7, the upper portion 702B can be positioned at an angle θ₁ relative to a reference plane 710 that is substantially perpendicular to the PV module 706. In the second position 708, the upper portion 702B can be positioned at an angle θ₂ relative to the reference plane 710. One or both of the angles θ₁ and θ₂ can be about 10 degrees in some embodiments, or more or less than 10 degrees in other embodiments. It is not necessary that angles θ₁ and θ₂ be equal. Further, the angles θ₁ and θ₂ can represent two rotation “endpoints” corresponding to the first and second positions, with other positions being possible at any angle between the two endpoints.

FIG. 7 further depicts the interaction of some example incoming light rays 712A-712F with the detachable louver system 700 during a particular time of year, such as during summer. Some light rays, such as light ray 712A, may impinge directly on the PV areas 706A. Other light rays, including light ray 712B, may reflect off a primary louver 704 before impinging on the PV areas 706A. Some light rays 712C, 712D may reflect off a secondary louver 702 before impinging on the PV areas 706A. Still other light rays, such as light rays 712E and 712F, may reflect off a primary louver 704 and then reflect off a secondary louver 702 before impinging on the PV areas 706A. In this and other embodiments, the different positions of the secondary louvers 702 can be selected to maximize the amount of light that impinges on the PV areas 706A during different time periods throughout the year.

The adjustable secondary louvers 702 of FIG. 7 and other embodiments disclosed herein can be employed in stationary or reversible detachable louver systems that are aligned or non-aligned to improve the efficiency of a corresponding PV module to which the detachable louver system is mounted. For instance, the detachable louver system 700 of FIG. 7 can be a stationary detachable louver system, either aligned or non-aligned, where the adjustable secondary louvers 702 can increase the amount of energy generated by the PV module 706 compared to a stationary detachable louver system that lacks adjustable secondary louvers. Alternately, in some embodiments, reversible detachable louver systems can employ fixed secondary louvers.

Returning to FIGS. 5A-5C, the secondary louvers 510 can be characterized by a height hₛ that may be greater than, less than, or equal to a height hₚ of the primary louvers 504. In some embodiments, the height hₛ of the secondary louvers 510 can be about 1.2 inches, while the height hₚ of the primary louvers 504 can be about 1.5 inches. In other embodiments, the heights hₛ and hₚ of the secondary and primary louvers 510, 504 can be different than the values stated herein.

The secondary louvers 510 can alternately or additionally be characterized by an angle θ₃ relative to the plane of the PV module 502. In some embodiments, the secondary louvers 510 can be fixed with respect to the primary louvers 504 such that the angle θ₃ is constant.

Alternately, the secondary louvers 510 can be adjustable with respect to the primary louvers 504, similar to the secondary louvers 702 of FIG. 7. In contrast to the secondary louvers 702 of FIG. 7, however, each of secondary louvers 510 can be rotated about an axis A₁ that is substantially collinear with the base of the secondary louver 510, such that the angle θ₃ varies depending on the amount of rotation of each secondary louver 510 about its corresponding axis A₁.

In this and other embodiments—such as the embodiment of FIG. 7—position adjustments of each secondary louver 510 via rotation about an axis A₁ can be enabled by employing central reflectors 508 that correspond to the central reflector 614 of FIG. 6D so as to rotatably support secondary louvers 510. For example, with combined reference to FIGS. 5A-5C and 6D, each of the central reflectors 508 can include second notches 622 to accommodate the secondary louvers 510 between the first and second positions and/or any position in between, an adjust lever 624, holding slots 626 securing the adjust lever 624 to the central reflector 508 while allowing the adjust lever to move axially with respect to the central reflector 508 through the holding slots 626, fasteners 628 securing the secondary louvers 510 to the adjust lever 624, and locking tabs 630 holding the base of each secondary louver 510 in place and fixing a corresponding axis of rotation A₁ of each secondary louver 510.

In this and other embodiments, the adjust lever 624 may be responsive to applied forces to move the secondary louvers 510 between at least the first position shown in FIG. 5B and the second position represented by reference plane 512 in FIG. 5B. For instance, by applying an axial force to the adjust lever 624, the adjust lever 624 may move axially through the holding slots 626. Further, when the adjust lever 624 is secured to the secondary louvers 510 via fasteners 628, axial movement of the adjust lever 624 can cause each of the secondary louvers 510 to rotate about a corresponding axis A₁ at the base of each secondary louver 510

When the secondary louvers 510 are in the first position shown in FIG. 5B, an axial force applied to the adjust lever 624 in the positive y-direction can move the secondary louvers 510 to the second position 512. Alternately, when the secondary louvers 510 are in the second position 512, an axial force applied to the adjust lever 624 in the negative y-direction can move the secondary louvers 510 to the first position depicted in FIG. 5B. Alternately, axial forces in the positive or negative y-directions can be applied to the adjust lever 624 to move the secondary louvers 510 to one or more other positions between the first and second positions.

As described above, movement of the secondary louvers 510 between the first position and the second position can be accomplished using an adjust lever, such as adjust lever 624, coupled to the secondary louvers 510. However, embodiments of the invention can alternately include secondary louvers that are adjustable in other ways between two or more positions, the different positions of the secondary louvers being configured to maximize the amount of energy generated by a corresponding PV module during different times of the year.

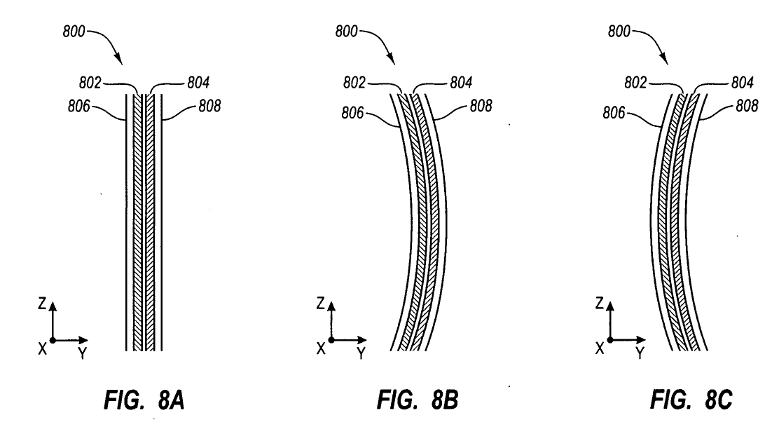

For example, FIGS. 8A-8C disclose an example secondary louver 800 that is adjustable, without the use of an adjust lever, between at least a first position depicted in FIG. 8B, and a second position depicted in FIG. 8C. For instance, the secondary louver 800 can comprise one or more thermally sensitive materials configured to distort the secondary louver 800 between the first position of FIG. 8B and the second position of FIG. 8C depending on the ambient temperature of the secondary louver 800. The first and second positions of FIGS. 8B and 8C may correspond to two “extreme” distortion positions, whereas the secondary louver 800 may also be configured to distort to one or more other positions between the first and second positions, such as a neutral position shown in FIG. 8A.

As shown in FIGS. 8A-8C, the secondary louver 800 can comprise a thermally sensitive substrate including first and second expansion layers 802, 804 coupled together with an adhesive, such as EVA. The secondary louver 800 can further comprise a first reflective layer 806 applied to the first expansion layer 802 and a second reflective layer 808 applied to the second expansion layer 804. The first and second reflective layers 806, 808 can be configured to reflect incoming light rays from the sun or from a primary louver onto PV areas of a corresponding PV module.

In some embodiments, the first expansion layer 802 and second expansion layer 804 can each comprise aluminum, copper, stainless steel, PET, polyvinyl chloride, or the like or any combination thereof. Alternately or additionally, the first expansion layer 802 can be approximately 20 mils thick, while the second expansion layer 804 can be approximately 30 mils thick. Alternately or additionally, the first expansion layer 802 can be greater or less than 20 mils thick and/or the second expansion layer 804 can be greater or less than 30 mils thick.

To enable distortion and movement of the secondary louver 800 between the first position of FIG. 8B and second position of FIG. 8C, the first expansion layer 802 may have a first coefficient of thermal expansion α₁, while the second expansion layer 804 may have a second coefficient of thermal expansion α₂ that is greater than α₁. It is appreciated that α₁ and α₂ may be characteristic of, respectively, the first and second expansion layers 802.

Accordingly, the materials from which the first and second expansion layers 802, 804 are made and the amount of material used for each of first and second expansion layers 802, 804 can be selected such that, at a predetermined average temperature, the first and second expansion layers 802, 804 are the same length, tending towards the neutral position shown in FIG. 8A. However, when the ambient temperature increases above the predetermined average temperature, the difference between α₁ and α₂ can cause the second expansion layer 804 to expand lengthwise more than first expansion layer 802, tending to distort the secondary louver 800 towards the position shown in FIG. 8B since the first and second expansion layers 802, 804 are coupled together. Alternately, when the ambient temperature decreases below the predetermined average temperature, the difference between α₁ and α₂ can cause the second expansion layer 804 to contract lengthwise more than first expansion layer 802, tending to distort the secondary louver 800 towards the position shown in FIG. 8C.

In the embodiment of FIGS. 8A-8C, warmer ambient temperatures characteristic of summer time may cause the secondary louver 800 to distort to or towards the position shown in FIG. 8B. Analogously, more moderate ambient temperatures characteristic of spring and fall times may cause the secondary louver 800 to move to or towards the position shown in FIG. 8A. Analogously, cooler ambient temperatures characteristic of winter time may cause the secondary louver 800 to distort to or towards the position shown in FIG. 8C.

Whereas ambient temperature throughout the year can vary gradually and continuously, as opposed to discretely, the position of the secondary louver 800 can also vary gradually and continuously throughout the year depending on the ambient temperature. Further, the changes in position of the secondary louver 800 can occur automatically without the use of a manually operated or motorized adjust lever.

Further, in this and other embodiments, the secondary louver 800 can rotate about an axis at a base of the secondary louver 800, or anywhere else along the secondary louver 800 height. Alternately or additionally, the base of the secondary louver 800 can be positioned at a predetermined height about the corresponding PV module.

G. Perimeter Louvers

Returning briefly to FIGS. 5A-5C, and as mentioned above, the detachable louver system 500 and other embodiments can implement two or more perimeter louvers arranged on opposite sides A and B along the perimeter of the detachable louver system 500. For instance, the frames 118 and 506 of FIGS. 1A-1D and 5A-5C can comprise perimeter louvers. Generally speaking, perimeter louvers can be configured to reflect light incident on all or a portion of the perimeter of a detachable louver system, e.g. incident along sides A and B of detachable louver systems 104 and 500, onto PV areas of a corresponding PV module.

Similar to the different cross-sectional shapes that can be employed for the primary louvers described above with respect to FIGS. 2A-2F, a cross-sectional shape of each perimeter louver can be one or more of: symmetric, asymmetric, substantially triangular, quasi-triangular, or the like, and can include one or more linear, curved, or curvilinear sides.

In some embodiments, foam tape can be used to secure the primary louvers to the perimeter louvers, such as the foam tape 119 of FIG. 1B securing primary louvers 116 to frame 118. Alternately or additionally, mechanical interference and/or friction can be employed to secure the primary louvers to the perimeter louvers. For example, FIGS. 9A and 9B depict an example perimeter louver 900 that employs friction to secure the primary louvers to the perimeter louver 900.

FIGS. 9A and 9B depict, respectively, a front view, and an end view of perimeter louver 900. As shown in FIG. 9A, the perimeter louver 900 can include a plurality of notches 902. One or more slots 904, 906 can optionally be formed at the base of each notch 902 that connect into the notch 902. Each notch 902 can be sized and shaped to accept one end, or a portion of one end, of a corresponding primary louver. In particular, the notches 902 can accept primary louvers having cross-sectional shapes that are complementary in size and shape to the notches 902. The difference in size and/or shape of the notches 902 compared to the cross-sectional shapes of the primary louvers can be selected to be sufficiently small to ensure that friction can secure the ends of the primary louvers within the notches 902 after the ends of the primary louvers are inserted into the notches 902.

The slots 904, 906 can be configured to receive bottom portions of corresponding primary louvers to ensure the primary louvers are frictionally secured within the perimeter louver 900.

As best shown in FIG. 9B, the perimeter louver 900 can optionally include a folded step 908. The folded step 908 can be disposed along an edge of the base of the perimeter louver 900 that is furthest away from a corresponding PV module when the perimeter louver 900 is assembled in a detachable louver system attached to the PV module. For instance, FIG. 9C depicts the perimeter louver 900 mounted on a PV module 910. The PV module 910 can be supported by a module frame 912 that extends forward beyond a front plate 910A of the PV module. Accordingly, the folded step 908 can be formed in perimeter louver 900 to accommodate the module frame 912 when the perimeter louver 900 is mounted on PV module 910.

The perimeter louver 900 can further include two folded edges 914A, 914B shown in FIG. 9B that can be configured to provide structural support to the perimeter louver 900. Further, FIG. 9B depicts an opening 916 in the cross-sectional shape of perimeter louver 900. Although perimeter louver 900 includes an open cross-sectional shape, embodiments of the invention can include perimeter louvers with closed cross-sectional shapes.

In some embodiments, the perimeter louver 900 can be formed with opening 916 to accommodate tooling used in forming the perimeter louver 900. Alternately or additionally, the perimeter louver 900 can be formed with a closed cross-sectional shape, e.g. lacking an opening 916, and can be formed using a continuous roll-forming process.

The perimeter louver 900 can be characterized by one or more perimeter louver 900 parameters, including a height h₁, a width w₁, a step height h₂, a step width w₂, folded edge 914A, 914B widths w₃ and w₄, opening width w₅, notch height h₃, angle α, a height h₄ from the base of the perimeter louver 900 to the base of each notch 902, a spacing s₁ between the adjacent slots 904, 906 of each notch 902, a spacing s₂ between adjacent slots 906, 904 of different notches 902, a size and shape of the notches 902, the quantity of notches 902 formed in the perimeter louver 900, and/or a length l of the perimeter louver 900.

In some embodiments, the perimeter louver 900 and/or primary louvers that are inserted into the notches 902 can be laminated with or otherwise include a reflective layer on the outer surface of the perimeter louver 900 and/or primary louver. For instance, in FIG. 9B, the perimeter louver 900 can include a reflective layer 918 disposed on the outer surface of perimeter louver 900. In some cases, the configuration of the perimeter louver 900 can prevent delamination of the reflective layer 918 on the perimeter louver 900 and/or on the primary louvers received into notches 902, as will be discussed in greater detail below.

H. Aspects of Some Louvers and Central Reflectors

The primary louvers, secondary louvers, perimeter louvers (collectively “louvers”), and/or central reflectors implemented in detachable louver systems according to embodiments of the invention can be made from a variety of different substrate materials. For instance, the louvers and/or central reflectors can comprise aluminum, stainless steel, extruded plastic, or the like or any combination thereof. Alternately or additionally, the louvers and/or central reflectors can comprise reflective layers that are laminated or otherwise attached to the louvers or central reflectors.

1. Continuous Roll Forming

Additionally, the louvers and/or central reflectors can be formed using any one of a variety of processes. For instance, louvers can be formed using a cutting and stamping method as described above with respect to FIGS. 6A-6D. Alternately or additionally, louvers and/or central reflectors can be formed from plastic using a plastic extrusion method. Alternately or additionally, louvers and/or central reflectors can be formed using a continuous roll forming process. For example, FIGS. 10A and 10B depict, respectively, a method 1000 of forming a plurality of primary louvers from a continuous roll of substrate material, and an example primary louver 1002 formed according to the method 1000.

The method 1000 can be used to form primary louvers 1002 from a continuous roll or sheet of substrate material, such as a roll or sheet of aluminum or stainless steel. For instance, the end view of FIG. 10B depicts substrate material 1004 that has been formed into primary louver 1002 While the method 1000 will be discussed in the context of continuously roll forming primary louvers 1002, the method 1000 can alternately or additionally be employed to continuously roll form secondary louvers, perimeter louvers, and/or central reflectors.

The method 1000 begins by laminating 1006 one side of the substrate material 1004 with a reflective layer 1008. The reflective layer 1008 can comprise a silver film, a plastic film, or a reflective layer made from other suitable material(s) having a hemispherical reflectivity of at least 90% or more. In some embodiments, the hemispherical reflectivity of reflective layer 1008 can be as high as or higher than 96%. Alternately, the hemispherical reflectivity of reflective layer 1008 can be less than 90%.

Optionally, an outer layer 1009 can be applied over the reflective layer 1008. The outer layer 1009 can have a surface porosity that is 0.1% or lower. In this example, the outer layer 1009 can comprise polymethyl methacrylate (“PMMA”), PET, or the like or any combination thereof. By implementing an outer layer 1009 with such a low surface porosity, the outer layer 1009 can minimize or substantially prevent the buildup of snow and/or ice on the primary louver 1002 as snow can tend to slide off of the primary louver 1002 and/or ice can tend to not form on the primary louver 1002 to begin with.

Returning to FIG. 10A, the method 1000 can continue by cutting 1010 the continuous roll of substrate material 1004 to width, which can include cutting the continuous roll of substrate material 1004 into sheets as wide as the length l of the primary louvers 1002. The cutting step 1010 can be performed using a laser cutter, continuous mechanical slitter, or other cutting device. After cutting 1010 the substrate material 1004 to width, the substrate material 1004 can be continuously shaped 1012 and cut 1014 into individual primary louvers 1002. In some embodiments, the continuous shaping 1012 and cutting 1014 can be performed by feeding the substrate material 1004 into a roll-forming machine having a series of rollers and an end cut-off device, such as a laser cutter, to shape and cut the substrate material 1004.

The method 1000 is one example of a continuous roll forming process that can be employed to mass-produce louvers and/or central reflectors for use in detachable louver systems. In some embodiments, one or more of the steps of the method 1000 can be performed in a different order than described herein. For instance, the sheet of substrate material 1004 can be cut 1010 to width before or after laminating 1006 one side of the substrate material 1004 with a reflective layer 1008. Alternately or additionally, the method 1000 can include other steps. For example, the method 1000 can optionally include notch- and/or slot-forming steps using a laser cutter or other cutter. The notch- and/or slot-forming steps can be employed to form, e.g., the first and second notches 616, 622 of the central reflector 614 of FIG. 6D, and/or the notches 902 and slots 904, 906 of perimeter louver 900 of FIGS. 9A-9C. Other steps can optionally be included in the method 1000 of FIG. 10A as well.

Alternately or additionally, the method 1000 can be a completely or substantially automated process that does not require significant human intervention. As such, the louvers 1002 produced according to the method 1000 can be produced with little or no human labor involved in order to reduce the cost of producing the louvers 1002.

In some embodiments, the primary louvers 1002—or other louvers or central reflectors produced using the method 1000 of FIG. 10A—can be densely packed for shipment in a condensed form, before being assembled with one or more perimeter louvers 900 (FIGS. 9A-9C) into a relatively more bulky detachable louver system locally at an installation site. In particular, the shape of the primary louvers 1002 depicted in FIG. 10B can be such that primary louvers 1002 can be stacked one on top of another with a minimum of empty space between the stacked primary louvers 1002, allowing the primary louvers 1002 to be densely stacked and/or shipped to an installation site.

2. Delamination Protection

With combined reference now to FIGS. 9A-9C and 10B, aspects of a detachable louver system including one or more perimeter louvers 900 and primary louvers 1002 will be discussed in additional detail. As already mentioned, each of perimeter louvers 900 and primary louvers 1002 can include a reflective layer 918, 1008, respectively, disposed on the outer surface of perimeter louvers 900 and primary louvers 1002. In some cases, the reflective layers 918, 1008 can be sensitive to light and/or other environmental factors, especially at cut edges of the reflective layers 918 and 1008, such as at the edges of notches 902 and/or at the edges A and B of primary louvers 1002. In particular, exposure of the cut edges of the reflective layers 918, 1008 to sunlight and/or other environmental factors can cause the reflective layers 918, 1008 to delaminate from the perimeter louvers 900 and primary louvers 1002. Such delamination of the reflective layers 918, 1008 can ultimately reduce the useful life of the perimeter louvers 900 and/or primary louvers 1002 if not addressed.

However, the configuration of the perimeter louver 900 can prevent delamination of the reflective layers 918, 1008 at one or more of the cut edges of the notches 902 and/or edges A and B of primary louvers 1002. In particular, when perimeter louvers 900 and primary louvers 1002 are used to form a detachable louver system, the ends of primary louvers 1002 can be received through notches 902 and slots 904, 906 such that the edges A and B of primary louvers 1002 can be protected from sunlight so as to prevent delamination of the reflective layer 1008 at the edges A and B. For instance, FIGS. 1A and 1B depict an assembled detachable louver system 104 where the ends of primary louvers 116 are covered by a frame 118 such that the edges of the primary louvers 116 are generally not exposed to sunlight during operation.

Returning to FIGS. 9A-9C and 10B, and with respect to the cut edges of the notches 902 of the perimeter louvers 900, when the notches 902 are cut in the perimeter louvers 900, a portion of the reflective layer 918 can be stretched and dragged into each notch 902 by the notch-cutting process. Further, when a primary louver 1002 is inserted through the a notch 902, friction between the primary louver 1002 and the portion of the reflective layer 918 already present in the notch 902 can result in the primary louver 1002 dragging the portion of the reflective layer 918 further into the notch 902. Further, friction between the primary louvers 1002, the notches 902 and/or the portions of the reflective layer 918 present in the notches 902 can ensure that the portions of the reflective layer 918 remain tucked inside the perimeter louver 900 such that the portions of the reflective layer 918 are not exposed to sunlight during operation.

Alternately or additionally, after the primary louvers 1002 have been received in the notches 902, a sealant can be applied between the primary louvers 1002 and notches 902 to substantially prevent exposure of the cut edges of the reflective layer 918 to sunlight and to further secure the primary louvers 1002 to the perimeter louvers 900.

3. Increasing Photovoltaic Area Efficiency

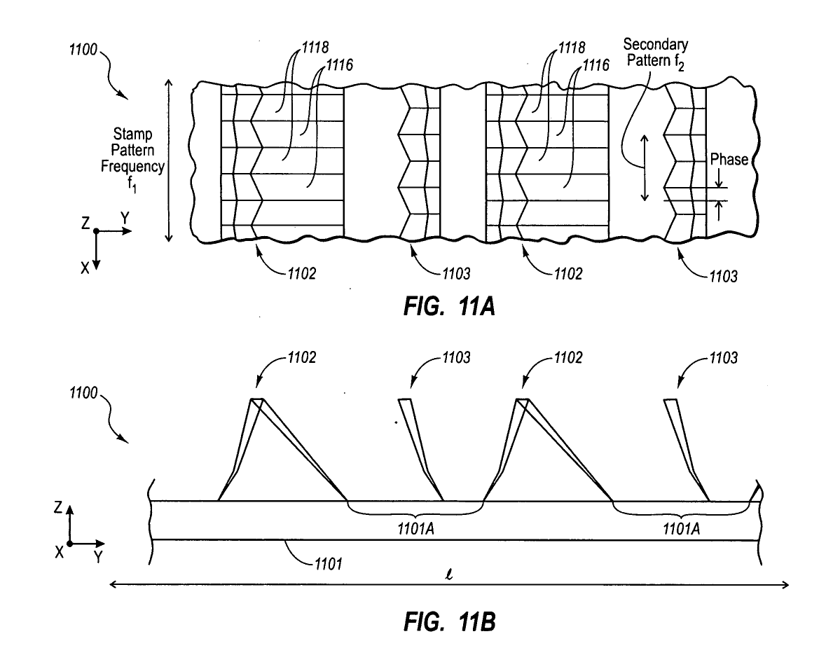

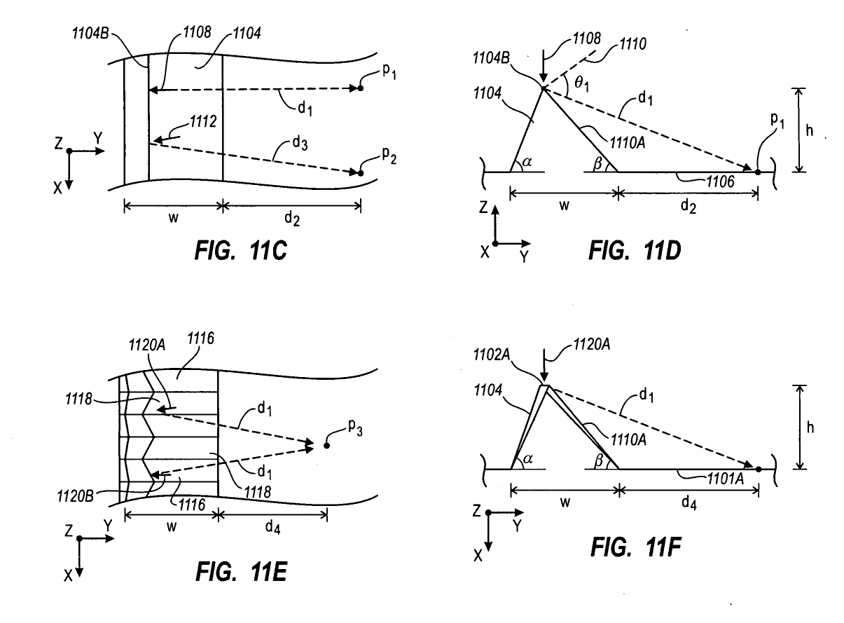

With reference next to FIGS. 11A and 11B, an example detachable louver system 1100 is disclosed that is configured to add a transverse x-component to the angle of reflection of incoming light rays relative to the length l of the detachable louver system 1100. The addition of a transverse reflection component to the incoming light rays can minimize the longitudinal y-distance the light rays travel before impinging on a corresponding PV area, thereby allowing the detachable louver system 1100 to be used in conjunction with a PV module 1101 having a relatively smaller percentage of PV areas 1101A than a PV module used with a detachable louver system that does not add a transverse reflection component, while still generating substantially the same amount of energy.

As shown in FIGS. 11A and 11B, the detachable louver system 1100 can include a plurality of primary louvers 1102 and a plurality of secondary louvers 1103. As will be described in more detail to follow, one or both of the primary louvers 1102 and secondary louvers 1103 can be configured to add a transverse x-component, relative to the length l of detachable louver system 1100, to the angle of reflection of light rays incident on the primary louvers 1102 and/or secondary louvers 1104. The addition of the transverse x-component to the angle of reflection of incident light rays can allow the width w of each PV area 1101A to be smaller than the width of PV areas required for primary louvers that do not add a transverse x-component to the angle of reflection, while still allowing the PV areas 1101A to collect the same amount of reflected light rays. As a result, the PV module 1101 can use a relatively smaller percentage of PV areas to generate the same amount of electricity as a PV module and detachable louver system that does not add a significant transverse x-component to the angle of reflection.

The principle of this and other embodiments will be described with respect to FIGS. 11C-11F. FIGS. 11C and 11D depict, respectively, a top view and an end view of a primary louver 1104 that does not add a significant transverse reflection component to incoming light rays. FIGS. 11E and 11F depict, respectively, a top view and an end view of a primary louver 1102 that does add a significant transverse reflection component to incoming light rays. Further, it is assumed in FIGS. 11C-11F that each of primary louvers 1104 and 1102 is aligned east to west lengthwise—i.e., the x-axis generally runs east to west.

In the embodiment of FIGS. 11C and 11D, the primary louver 1104 can be characterized by a height h, a width w, and angles α and β. Further, the primary louver 1104 can be configured such that a normal line 1110 substantially perpendicular to a side 1104A of the primary louver 1104 at any point on the side 1104A does not include a significant transverse x-component.

Moreover, in some embodiments, the minimum width of a PV area that can capture most of the light reflected off the side 1104A can depend on the longitudinal y-distance that a light ray reflected off the primary louver 1104 near the apex 1104B of the primary louver 1104 will travel before impinging on the corresponding PV area 1106.

For example, light ray 1108 incident near the apex 1104B of primary louver 1104 can be reflected off primary louver 1104 and travel a total distance d₁ before impinging on the PV area 1106 at a point p₁ that is a y-distance d₂ away from the base of primary louver 1104. Because the primary louver 1104 is aligned east to west, and since the normal line 1110 does not include a significant transverse x-component, the primary louver 1104 does not add a significant transverse x-component to the angle of reflection of reflected light ray 1108A.

In FIG. 11C, the light ray 1108 may be a midday light ray having an angle of incidence substantially lacking a transverse x-component, while including a vertical z-component and a longitudinal y-component. In contrast, a morning or evening light ray 1112 (FIG. 11C) may have an angle of incidence at the primary louver 1104 that includes a transverse x-component, in addition to having substantially the same vertical z-component and longitudinal y-component as the light ray 1108. Because the primary louver 1104 does not add a significant transverse x-component to the angle of reflection of incident light rays, the reflected light ray 1112 will travel a distance d₃ to impinge on PV area 1106 at a point p₂ that is the same y-distance d₂ from the base of primary louver 1104 as the point p₁. Accordingly, the minimum width of a PV area 1106 that can capture most of the light reflected off the side 1104A of primary louver 1104 is at least d₂.

In contrast, the minimum width of a PV area that can capture most of the light reflected off the side of a primary louver that adds a transverse reflection component to incoming light rays can be less than the distance d₂. For instance, FIGS. 11E and 11F disclose aspects of primary louver 1102 characterized by a height h, a width w, and average angles α and β that are substantially equal to the height h, width w, and angles α and β of the primary louver 1104 of FIGS. 11C and 11D.

In the example of FIGS. 11E and 11F, the primary louver 1102 can include a plurality of corrugations 1116 and 1118 formed therein. Each corrugation 1116, 1118 can be substantially planar, with the corrugations 1116 being substantially parallel to each other, and the corrugations 1118 being substantially parallel to each other. In contrast, however, the corrugations 1116 are not substantially parallel to the corrugations 1118. Thus, a normal line substantially perpendicular to a corrugation 1116 at any point on the corrugation 1116 can have a positive x-component, while a normal line substantially perpendicular to a corrugation 1118 at any point on the corrugation 1118 can have a negative x-component.

Assuming that the primary louver 1102 is aligned lengthwise east to west, when an incoming midday light ray 1120A, e.g., the light ray 1120A substantially lacks an angle of incidence with a transverse x-component relative to the length l of detachable louver system 1100, is incident on the corrugation 1116 near the apex 1102A of primary louver 1102, the corrugation 1116 can add a positive transverse x-component to the angle of reflection of light ray 1120A, relative to the length l, by virtue of the fact that the normal line of corrugation 1116 has a positive x-component. Analogously, when an incoming midday light ray 1120B is incident on the corrugation 1118 near the apex 1102A, the corrugation 1118 can add a negative transverse x-component to the angle of reflection of light ray 1120B, relative to the length l, by virtue of the fact that the normal line of corrugation 1118 has a negative x-component.

In the example of FIGS. 11E and 11F, both light rays 1120A and 1120B can travel a distance d₁ to impinge on the PV area 1101A at a point p₃ that is a longitudinal distance d₄ away from the base of primary louver 1102. In this case, the total distance d₁ traveled by each of light rays 1120A, 1120B can be substantially equal to the distance d₁ traveled by light ray 1108 of FIGS. 11C and 11D. However, because the primary louver 1102 adds a transverse x-component to the angles of reflection of light rays 1120A and 1120B relative to the length l of detachable louver system 1100, the distance d₄ from the base of primary louver 1102 to the point p₃ can be less than the distance d₂ from the base of primary louver 1104 to the point p₁. As a result, the PV area 1101A of FIG. 11F can be narrower than the PV area 1106 of FIG. 11D, while receiving substantially the same amount of reflected light rays as the PV area 1106.

Note that for morning and/or evening light rays (not shown) that impinge on the primary louver 1102 near its apex 1102A and that have an angle of incidence including a transverse x-component relative to the length l of detachable louver system 1100, a positive or negative transverse x-component can still be added to their angle of reflection by a corrugation 1116 or 1118 such that the morning and/or evening light rays also impinge on the PV area 1101A at a distance d₄ from the base of primary louver 1102.

In the embodiment of FIGS. 11B and 11A, the detachable louver system 1100 can include primary and/or secondary louvers 1102, 1103 that include corrugations in order to add a transverse x-component to the angle of reflection of incoming light rays relative to the length l of the detachable louver system 1100. In other embodiments, the primary and/or secondary louvers 1102, 1103 can alternately or additionally include one or more other features or treatments that add a transverse x-component to the angle of reflection of incoming light rays relative to the length l of the detachable louver system 1100. For example, the primary and/or secondary louvers 1102, 1103 can be textured, corrugated, embossed, or otherwise treated such that a transverse x-component is added to the angle of reflection of light rays that reflect off of the primary and/or secondary louvers 1102, 1103.

4. Increasing Photovoltaic Area Density

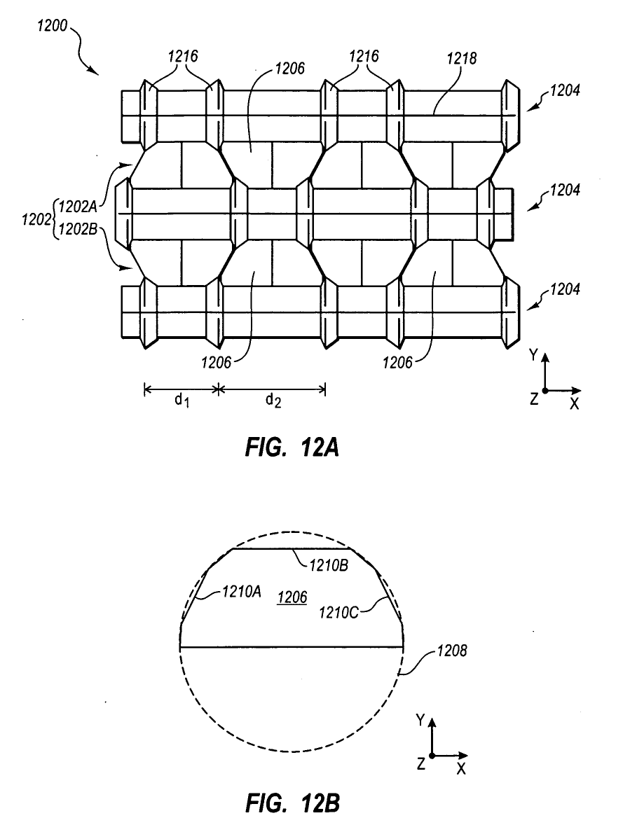

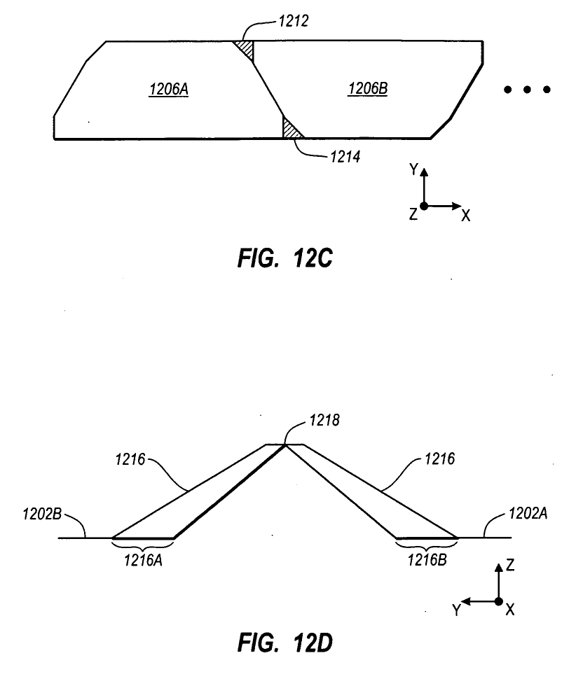

Turning next to FIGS. 12A-12D, an example PV system 1200 is disclosed that can incorporate various features to maximize the density of PV material in a given PV area. The PV system 1200 can include a PV module comprising a plurality of PV areas 1202 arranged in rows 1202A, 1202B, etc., and a detachable louver system comprising a plurality of primary louvers 1204.

Each of rows 1202A and 1202B can be made up of a plurality of PV cells 1206, with a single example PV cell 1206 being disclosed in FIG. 12B. The PV cells 1206 can have a quasi-trapezoidal shape for increased PV density in the rows 1202A. In particular, the PV cells 1206 can be formed from substantially circular wafer stock, represented in FIG. 12B by reference circle 1208. The substantially circular wafer stock 1208 can be cut in half, each half being used to form a separate PV cell 1206. Further, the substantially circular wafer stock 1208 can be cut along edges 1210A, 1210B and 1210C to form the PV cell 1206. The material cut away from edges 1210A-1210C is generally unusable and discarded. By cutting the substantially circular wafer stock 1208 as shown in FIG. 12B, only about 3% of the substantially circular wafer stock 1208 may be discarded in some embodiments, preserving approximately 97% of the substantially circular wafer stock 1208 for use in a row 1202A or 1202B.

Generally, the PV cells in each of rows 1202A and 1202B can be arranged side-by-side in an alternating first orientation and second orientation that is a reverse orientation of the first orientation. For instance, FIG. 12C depicts a close-up view of two PV cells 1206A and 1206B of row 1202A arranged side by side. Due to the shape of the PV cells 1206A, 1206B, two areas 1212 and 1214 can exist within the confines of row 1202A that are not covered by either of PV cells 1206A or 1206B. As a result, light rays impinging on the areas 1212 and 1214 may not be converted to electrical energy.

To capture light rays that would otherwise impinge on the areas 1212, 1214, the primary louvers 1204 can include corrugations 1216 that cover the areas 1212, 1214, such that light rays that would have impinged on the areas 1212, 1214 are reflected by the corrugations 1216 onto the PV cells 1206.

In some embodiments, each of primary louvers 1204 can be formed from a flat sheet of material comprising aluminum, stainless steel, plastic, or the like. First, the corrugations 1216 can be formed in the flat sheet and alternately spaced distances d₁ and d₂ apart from each other. Each of the corrugations 1216 formed in the flat sheet can be symmetric or asymmetric and can have a substantially triangular cross-section. After forming the corrugations 1216, the flat sheet can be bent along a line substantially perpendicular to the corrugations 1216 to form the apex 1218 of the primary louver 1204.

FIG. 12D depicts an end view of a primary louver 1204. As shown in FIG. 12D, an end 1216A and 1216B of each of corrugations 1216 can be substantially parallel to the surface of rows 1202A and 1202B.

As mentioned above, the corrugations 1216 can be alternately spaced distances d₁ and d₂ apart. The distances d₁ and d₂ can be selected to accommodate the alternating first and second orientations of the PV cells 1206 in each row 1202A, 1202B. In this manner, the ends 1216A and 1216B of the corrugations 1216 can cover at least or portion or substantially all of the areas 1212, 1214 between adjacent PV cells 1206 to reflect the light rays that would otherwise impinge on areas 1212, 1214 onto one of the PV cells 1206.

### III. Shaping Louvers to Optimize Annual Energy Generation

The shape of the primary louvers used in detachable louver systems according to embodiments of the invention can be determined by iterating and optimizing on specific and defined degrees of freedom of a primary louver to maximize the power generated by a corresponding PV module throughout the year. This same iterative process can alternately or additionally be applied to determine the optimum shape of secondary louvers, central reflectors, and/or perimeter louvers included in the detachable louver system.

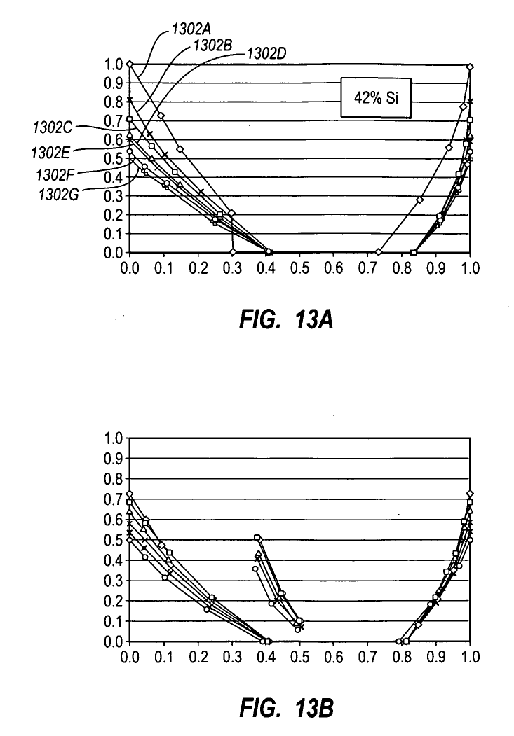

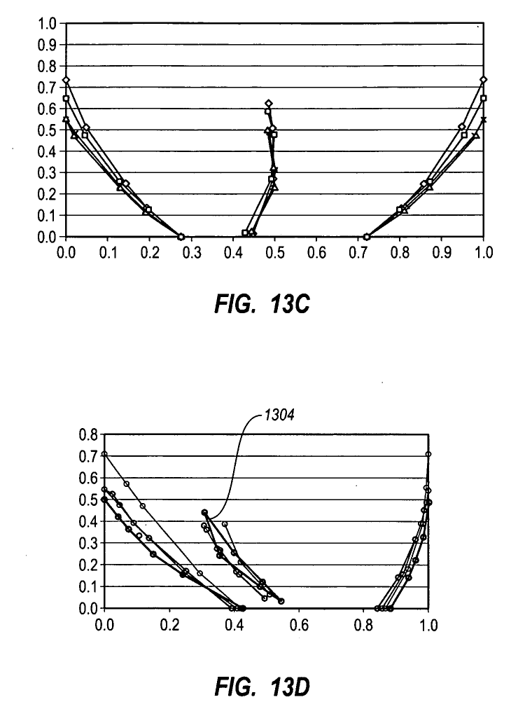

For example, FIG. 13A depicts a first set of louver configurations of varying heights normalized to a unit width. The term “unit width” refers to the shortest longitudinal distance between the apex of one primary louver and the apex of an adjacent primary louver. FIG. 13 includes curves representative of seven different asymmetric primary louver configurations having curvilinear sides, the seven different configurations denoted 1302A-1302G.

The actual dimensions of any one of primary louver configurations 1302A-1302G can be determined by multiplying by the unit width. For instance, the actual height of configuration 1302A can be determined by multiplying the normalized height of configuration 1302A, which happens to be 1, by the unit width. As another example, the actual height of configuration 1302G can also be determined by multiplying the normalized height of configuration 1302G, which happens to be 0.5, by the unit width.

Further, as noted in FIG. 13A, the primary louver configurations 1302A-1302G can be designed for a PV module having PV areas comprising silicon with a PV area density of 42%. In other words, a PV module used in conjunction with the primary louver configurations 1302A-1302G can have a plurality of PV areas arranged in rows with non-PV areas between the rows, with the PV areas and the non-PV areas making up, respectively, 42% and 58% of the surface area of the PV module.

Similar to FIG. 13A, each of FIGS. 13B, 13C and 13D depicts a different set of louver configurations of varying heights normalized to a unit width. The configurations depicted in FIGS. 13B, 13C and 13D can be designed, respectively, for PV modules having PV area densities of about 40%, 45%, and 45%. Further, the louver configurations of FIGS. 13B-13D can include both primary louvers and secondary louvers.

Moreover, FIG. 13D depicts a possible secondary louver configuration 1304 comprising a closed shape. More particularly, the secondary louver configuration 1304 has a cross-sectional shape that is substantially triangular and that is closed on all three sides. In other embodiments, the cross-sectional shape of secondary louvers employed in detachable louver systems can be quasi-triangular or some other shape that is closed on all sides. Accordingly, embodiments of the invention include secondary louvers having a variety of different shapes that are closed on all sides.

After generating one or more normalized louver configurations such as depicted in each of FIGS. 13A-13D, simulations can be run to calculate the performance and/or efficiency of a given configuration. The performance calculations for multiple normalized louver configurations can optionally be compared to each other to identify a louver configuration that maximizes the amount of energy generated by a stationary PV module in conjunction with the identified louver configuration.

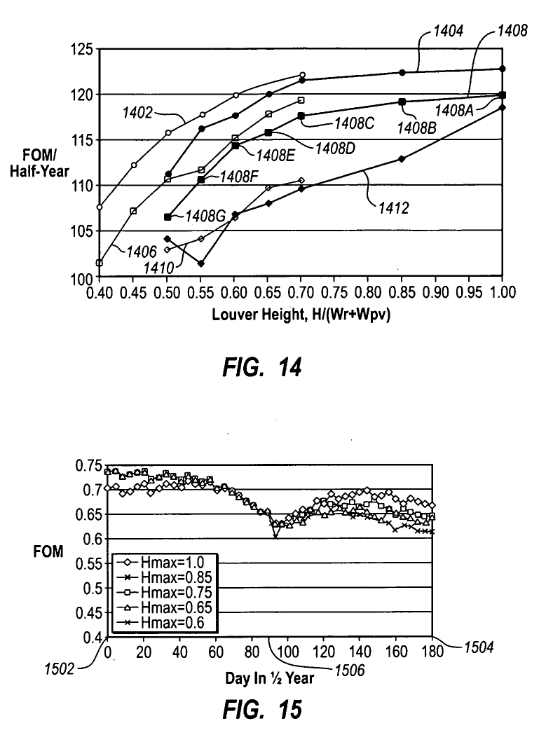

For example, FIG. 14 includes 6-month Figure of Merit (“FOM”) calculations for a variety of different louver configurations. Each of curves 1402, 1404, 1406, 1408, 1410, 1412 represents FOM calculations for a different set of louver configurations having varying normalized heights. The x-axis represents normalized height and the y-axis represents the 6-month FOM calculation.

In this example, each louver configuration included in each of the different sets of louver configurations can be a reversible louver configuration designed to be rotated approximately every six months. As such, the FOM calculations of this example can be 6-calculations. Alternately or additionally, a 1-year FOM calculation can be employed.

There can be several differences between each of curves 1402-1412. For instance, each of curves 1402 and 1404 can represent louver configurations designed for PV modules having PV area densities of 45%, whereas curves 1406 and 1408 can represent louver configurations designed for PV modules having PV area densities of 42%, and curves 1410 and 1412 can represent louver configurations designed for PV modules having PV area densities of 40%. Further, each of curves 1402, 1406 and 1410 can represent louver configurations having both primary louvers and secondary louvers, whereas each of curves 1404, 1408 and 1412 can represent louver configurations having only primary louvers.

In some embodiments, each one of curves 1402-1412 can include the 6-month FOM data for a given set of louver configurations designed for a given PV area density. For example, as already mentioned, the curve 1408 can represent a louver configuration that only has primary louvers and that is designed for a PV module having a PV area density of 42%. As such, the curve 1408 can represent the 6-month FOM calculations for each of the louver configurations 1302A-1302G of FIG. 13A. For instance, the louver configuration 1302A of FIG. 13A has a normalized height of 1.00. Thus, the data point 1408A in FIG. 14 located at (1.00, 120) can indicate that the louver configuration 1302A having a normalized height of 1.00 has a 6-month FOM of approximately 120. Similarly, data points 1408B-1408G can provide the 6-month FOM calculations for each of the louver configurations 1302B-1302G, respectively, of FIG. 13A.

Alternately or additionally, one or more of curves 1402, 1404, 1406, 1410 or 1412 can represent the 6-month FOM calculations for each of the louver configurations depicted in one or more of FIG. 13C or 13D or for louver configurations included in one or more other normalized sets of louver configurations not provided herein.

As can be seen from the data provided in FIG. 14, louver configurations used with larger PV area densities can generally have higher figures of merit than louver configurations used with smaller PV area densities at any given normalized height. For instance, at every normalized height, the louver configurations 1402 and 1404 used with 45% PV area densities have higher 6-month FOM calculations than the louver configurations 1406 and 1408 used with 42% PV area densities. Similarly, the louver configurations 1406 and 1408 have higher 6-month FOM calculations than the louver configurations 1410 and 1412 used with 40% PV area densities.

Notwithstanding the lower 6-month FOM calculations of the louver configurations used with lower PV area densities, the added cost of creating PV modules with greater PV area densities can outweigh the benefit of having a higher 6-month FOM. Accordingly, in some cases it can be desirable to use one of the louver configurations designed for use with lower PV area densities, such as the louver configurations represented by curves 1410 and 1412, even though the 6-month FOM calculations may not be as high as for other louver configurations designed for use with higher PV area densities, such as the louver configurations represented by curves 1402-1408.

FIG. 14 also illustrates how the inclusion of secondary louvers in a louver configuration can improve the 6-month FOM calculation for a given PV area density. For example, even though both of curves 1402 and 1404 represent louver configurations for use with PV modules having PV area densities of 45%, the 6-month FOM calculations for the louver configurations of curve 1402 are relatively higher than the 6-month FOM calculations for the louver configurations of curve 1404. Specifically, for example, the 6-month FOM calculation for the louver configuration of curve 1402 having a normalized height of 0.5 is about 116, whereas the 6-month FOM calculation for the louver configuration of curve 1404 having a normalized height of 0.5 is about 111.

As seen in FIG. 14, the 6-month FOM calculations tend to flatten starting at normalized louver heights of about 0.7, while decreasing sharply as the normalized louver heights are decreased below about 0.7. Based solely on the information of FIG. 14, then, a normalized louver height of 0.7 may maximize the amount of energy generated by a corresponding PV module. However, problems may exist with designing louvers having a normalized height of 0.7, such as early and late day shading caused by the louvers, added cost, aesthetics, wind drag, snow collection, debris collection, or the like, such that one or more other normalized heights may be more desirable.

FIG. 15 discloses another set of performance data for multiple normalized louver configurations that can be used to identify a louver configuration that maximizes the amount of energy generated by a PV module in conjunction with the identified louver configuration. Similar to FIG. 14, the louver configurations used in FIG. 15 may be reversible louver configurations that are changed approximately every six months.

FIG. 15 includes performance data for five louver configurations of varying normalized heights that are all designed for use with PV modules having a PV area density of 50%. In particular, the five louver configurations can have normalized primary louver heights of 1.0, 0.85, 0.75, 0.65, and 0.6, respectively. In the simulation of FIG. 15, and for each louver configuration, an FOM calculation was generated for every 5-day period for a half-year beginning at the winter solstice 1502 and ending at the summer solstice 1504, with each louver configuration being rotated midway through the half-year at the spring equinox 1506. Thus, the x-axis can represent the days in the half-year, and the y-axis can represent the 5-day FOM. It will be appreciated that the 5-day FOM calculations for the half-year from the summer solstice 1504 to the winter solstice 1502 for these same five louver configurations can basically be a mirror image of FIG. 15.

As can be seen in FIG. 15, the 5-day FOM calculations for each of the five louver configurations tend to decrease moving from the winter solstice 1502 to the spring equinox 1506, due to the changing angle of incoming light rays. However, by rotating each louver configuration at the spring (or fall) equinox 1506, the 5-day FOM calculations tend to increase moving from the spring equinox 1506 to the summer solstice 1504. Accordingly, FIG. 15 illustrates the general principle that a reversible detachable louver system can be employed to maximize the amount of energy generated by a corresponding PV module.

FIG. 15 additionally illustrates the performance of the five different louver configurations relative to each other throughout the half-year. For example, the louver configuration having a normalized primary louver height of 0.6 generally has a lower 5-day FOM calculations in the spring and summer than the other four louver configurations, making it relatively less efficient at reflecting light onto PV areas of a corresponding PV module at these times of year.

Accordingly, in some embodiments, the shape of the primary and/or secondary louvers used in a detachable louver system can be selected to maximize the amount of light generated by a corresponding PV module by iterating and optimizing on specific degrees of freedom, such as the normalized height and/or corresponding PV area density, of the primary and/or secondary louvers, as discussed above with respect to FIGS. 13A-15.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A detachable louver system, comprising:
a plurality of primary louvers arranged substantially parallel to each other and configured to reflect light rays incident on the plurality of primary louvers onto a plurality of photovoltaic areas of a photovoltaic module; and
a frame configured to support the plurality of primary louvers and to removably couple the detachable louver system to the photovoltaic module.

2. The detachable louver system of claim 1, wherein:
the plurality of primary louvers are shaped to maximize the amount of energy generated by the photovoltaic module over the course of a year in association with the detachable louver system;
a shape of each of the plurality of primary louvers is symmetric or asymmetric; and
the shape of each of the plurality of primary louvers comprises a substantially triangular shape or a quasi-triangular shape that is open along a base of each of the plurality of primary louvers.

3. The detachable louver system of claim 1, wherein the configuration of the detachable louver system depends on whether the photovoltaic module has an aligned orientation or a non-aligned orientation.

4. The detachable louver system of claim 1, further comprising a plurality of secondary louvers supported by the frame, the secondary louvers arranged substantially parallel to and interposed between the plurality of primary louvers and configured to reflect light incident on the secondary louvers from the sun, the primary louvers, or both, onto the plurality of photovoltaic areas.

5. The detachable louver system of claim 4, wherein the plurality of secondary louvers are adjustable with respect to the plurality of primary louvers between at least a first position and a second position, the first position configured to maximize the amount of light rays reflected from the secondary louvers to the plurality of photovoltaic areas during a first time of year and the second position configured to maximize the amount of light rays reflected from the secondary louvers to the plurality of photovoltaic areas during a second time of year.

6. The detachable louver system of claim 5, further comprising one or more central reflectors rotatably supporting the plurality of secondary louvers and arranged substantially perpendicular to the plurality of secondary louvers, the one or more central reflectors each including an adjust lever secured to each of the plurality of secondary louvers, the adjust lever being responsive to applied forces to move the plurality of secondary louvers from the first position to the second position and from the second position to the first position.

7. The detachable louver system of claim 5, wherein each of the plurality of secondary louvers comprises a thermally sensitive substrate configured to distort the secondary louver between the first position and the second position depending on ambient temperature of the detachable louver system.

8. The detachable louver system of claim 4, wherein each of the plurality of secondary louvers comprises a closed shape.

9. The detachable louver system of claim 4, wherein each of the plurality of primary louvers, each of the plurality of secondary louvers, or both, are configured to add a transverse component to the angle of reflection of light rays reflected off of each of the plurality of primary louvers, each of the plurality of secondary louvers, or both, relative to a length of the detachable louver system, thereby minimizing longitudinal distances the light rays travel before impinging on the photovoltaic areas.

10. The detachable louver system of claim 9, wherein each of the plurality of primary louvers, each of the plurality of secondary louvers, or both, are textured, corrugated or embossed to add a transverse component to the angle of reflection of light rays reflected off of each of the plurality of primary louvers, each of the plurality of secondary louvers, or both.

11. The detachable louver system of claim 1, wherein:
each of the plurality of photovoltaic areas comprises a plurality of photovoltaic cells arranged side-by-side;
each of the plurality of photovoltaic cells has a shape such that when two photovoltaic cells having the shape are laid side-by-side, one or more non-photovoltaic areas are present between each pair of photovoltaic cells;
each of the plurality of primary louvers includes one or more corrugations;
each of the corrugations includes an end that covers at least a portion of one of the non-photovoltaic areas; and
the corrugations are shaped such that light rays that would have otherwise impinged on the at least a portion of each non-photovoltaic area are reflected from the ends of the corrugations onto the plurality of photovoltaic cells.

12. The detachable louver system of claim 11, wherein the shape of each of the plurality of photovoltaic cells is quasi-trapezoidal, the plurality of photovoltaic cells within each photovoltaic area being alternately arranged side-by-side in a first orientation and a second orientation that is a reverse orientation of the first orientation.

13. The detachable louver system of claim 1, wherein the frame comprises two perimeter louvers arranged on opposite sides of the perimeter of the detachable louver system, the two perimeter louvers configured to reflect light incident at the opposite sides of the perimeter of the detachable louver system onto the plurality of photovoltaic areas.

14. The detachable louver system of claim 13, further comprising at least one central reflector arranged substantially perpendicular to the plurality of primary louvers, the at least one central reflector configured to support the plurality of primary louvers and to reflect light incident on the at least one central reflector from the plurality of primary louvers, the two perimeter louvers, or both, onto the plurality of photovoltaic areas.

15. The detachable louver system of claim 13, further comprising a plurality of air vents integrally formed in the plurality of primary louvers and the two perimeter louvers, the plurality of air vents configured to establish a high pressure-to-low pressure gradient from a front of the detachable louver system to a back of the detachable louver system when air flows across the detachable louver system.

16. The detachable louver system of claim 15, wherein the plurality of air vents are further configured such that air forced through the plurality of air vents caused by air flow across the detachable louver system substantially prevents debris from accumulating on the detachable louver system and the photovoltaic module.

17. The detachable louver system of claim 13, wherein each perimeter louver includes a plurality of notches formed on one side of the perimeter louver, each of the plurality of notches being configured to receive an end of each of the plurality of primary louvers and frictionally secure the plurality of primary louvers to the perimeter louver.

18. The detachable louver system of claim 17, wherein each of the plurality of primary louvers and each of the two perimeter louvers is laminated with a reflective layer having a hemispherical reflectivity of 90% or greater and each of the plurality of primary louvers and each of the two perimeter louvers comprises aluminum, stainless steel, or extruded plastic.

19. The detachable louver system of claim 18, wherein ends of the plurality of primary louvers are disposed within interiors of the two perimeter louvers, the disposition of the ends of the plurality of primary louvers within interiors of the two perimeter louvers substantially preventing environmental exposure of the ends of the plurality of primary louvers and substantially preventing delamination of the reflective layer from the ends of the plurality of primary louvers.

20. The detachable louver system of claim 18, wherein each of the plurality of primary louvers includes an outer layer having a surface porosity less than 0.1% to minimize buildup of ice and snow on the detachable louver system.

21. A photovoltaic system, comprising:
a photovoltaic module configured to remain stationary during operation throughout the year, the photovoltaic module comprising:
a plurality of photovoltaic areas configured to convert the energy of light rays incident thereon to electricity; and
a substantially transparent front plate disposed on top of the plurality of photovoltaic areas and configured to protect the plurality of photovoltaic areas from damage; and
a detachable louver system removably coupled to the photovoltaic module and configured to reflect light rays incident thereon onto the plurality of photovoltaic areas, the detachable louver system comprising a plurality of primary louvers arranged substantially parallel to each other.

22. The photovoltaic system of claim 21, wherein the photovoltaic module is aligned to the sun, each of the primary louvers is arranged lengthwise in a substantially east-to-west orientation, and the detachable louver system is configured to remain stationary in a first orientation relative to the photovoltaic module during operation throughout at least a first season of the year.

23. The photovoltaic system of claim 21, wherein the detachable louver system is configured to be removably coupled to the photovoltaic module in a first orientation during at least a first time of the year and in a second orientation during at least a second time of the year, the first orientation configured to maximize the amount of light rays reflected onto the photovoltaic areas throughout the first time of the year and the second orientation configured to maximize the amount of light rays reflected onto the photovoltaic areas throughout the second time of the year.

24. The photovoltaic system of claim 21, wherein the plurality of photovoltaic areas comprise a plurality of silicon rows, the plurality of primary louvers being positioned above areas of the photovoltaic module that are between the plurality of silicon rows with gaps between the plurality of primary louvers being positioned above the plurality of photovoltaic areas

25. The photovoltaic system of claim 24, further comprising means for detachably coupling the detachable louver system to the photovoltaic module and for aligning the gaps between the plurality of primary louvers with the plurality of photovoltaic areas.

26. The photovoltaic system of claim 25, wherein the means for detachably coupling the detachable louver system to the photovoltaic module and for aligning the spaces between the plurality of primary louvers with the plurality of photovoltaic areas include one or more of:
a plurality of movable spring clips attached to a back of the detachable louver system;
one or more slotted holes formed in the detachable louver system; or
one or more pins attached to the photovoltaic module and configured to be inserted into the one or more slotted holes.

27. A method of forming a louver, comprising:
laminating one side of a sheet of substrate material with a reflective layer;
cutting the sheet of substrate material to width;
shaping the substrate material into a plurality of louvers; and
cutting each of the plurality of louvers from the sheet of substrate material.

28. The method of claim 27, further comprising, prior to shaping the substrate material into a plurality of louvers, cutting a plurality of notches into the substrate material.

29. The method of claim 27, wherein cutting the sheet of substrate material to width comprises cutting the sheet of substrate material to a width equal to a length of each of the plurality of louvers.

30. The method of claim 27, wherein the step of cutting the sheet of substrate material to width, the step of cutting each of the plurality of louvers from the sheet of substrate material, or both, are performed by a laser cutter.

31. The method of claim 27, wherein the method comprises an automated process not requiring significant human intervention.

32. The method of claim 27, wherein the substrate material comprises one or more of aluminum or sheet metal.
